(19) United States
(12) Patent Application Publication
(10) Pub. No.: US 2025/0301668 A1
(43) Pub. Date: Sep. 25, 2025

(54) SEMICONDUCTOR MEMORY DEVICE

(71) Applicant: Kioxia Corporation, Tokyo (JP)

(72) Inventors: Yutaka SHIMIZU, Yokohama Kanagawa (JP); Maya INAGAKI, Yokohama Kanagawa (JP); Masaki NAKAMURA, Fujisawa Kanagawa (JP); Masato DOME, Kamakura Kanagawa (JP); Shoki ITO, Yokohama Kanagawa (JP); Kentaro WATANABE, Yokohama Kanagawa (JP)

(73) Assignee: Kioxia Corporation, Tokyo (JP)

(21) Appl. No.: 18/979,705

(22) Filed: Dec. 13, 2024

(30) Foreign Application Priority Data
Mar. 22, 2024 (JP) 2024-046465

(51) Int. Cl. H10B 80/00; H01L 23/00; H01L 25/065; H01L 25/18; H10D 89/60

(52) U.S. Cl. CPC H10B 80/00; H01L 24/08; H01L 25/0657; H01L 25/18; H10D 89/611; H01L 2224/08145; H01L 2924/1431; H01L 2924/14511

(57) ABSTRACT

A semiconductor memory device comprises: a semiconductor substrate; conductive layers; pad electrodes; a first wiring and a second wiring provided between the semiconductor substrate and the conductive layers; and via contact electrodes. The pad electrodes include: a first pad electrode having a signal inputted/outputted thereto/therefrom; and a second pad electrode and a third pad electrode applied with voltages. The semiconductor substrate is provided with a first transistor, a second transistor, a first diode, a second diode, and a clamp circuit. A part of the via contact electrodes overlapping the second pad electrode and electrically connected to the first transistor, the first diode, or the clamp circuit are commonly connected to the first wiring. Another part of the via contact electrodes overlapping the third pad electrode and electrically connected to the second transistor, the second diode, or the clamp circuit are commonly connected to the second wiring.

### CROSS-REFERENCE TO RELATED APPLICATIONS

This application is based upon and claims the benefit of Japanese Patent Application No. 2024-046465, filed on Mar. 22, 2024, the entire contents of which are incorporated herein by reference.

### BACKGROUND

### Field

The present embodiments relate to semiconductor memory devices.

### Description of the Related Art

There is known a semiconductor memory device comprising: a semiconductor substrate; a plurality of conductive layers stacked in a stacking direction intersecting a surface of the semiconductor substrate; a semiconductor column facing these plurality of conductive layers; and a gate insulating layer provided between the conductive layers and the semiconductor column. The gate insulating layer comprises a memory portion capable of storing data, such as an insulating electric charge accumulating film of silicon nitride (SiN), or the like, or a conductive electric charge accumulating film, such as a floating gate, for example.

### BRIEF DESCRIPTION OF THE DRAWINGS

FIG. 1 is a schematic circuit diagram showing a part of a configuration of a memory die MD;

FIG. 2 is a schematic circuit diagram showing a part of a configuration of a peripheral circuit PC;

FIG. 3 is a schematic exploded perspective view showing a configuration example of a semiconductor memory device according to a first embodiment;

FIG. 4 is a plan view schematically showing arrangement of a plurality of external pad electrodes according to the first embodiment;

FIG. 5 is a schematic circuit diagram showing configuration of the memory die MD;

FIG. 6 is a schematic circuit diagram showing a part of a configuration of the memory die MD;

FIG. 7 is a schematic circuit diagram showing a part of a configuration of the memory die MD;

FIG. 8 is a schematic cross-sectional view showing a part of a configuration of the memory die MD;

FIG. 9 is a schematic cross-sectional view showing a part of a configuration of the memory die MD;

FIG. 10 is a schematic cross-sectional view showing a part of a configuration of a chip C_{M};

FIG. 11 is a schematic circuit diagram showing a configuration of a semiconductor memory device including a protection circuit according to the first embodiment;

FIG. 12 is a schematic layout diagram showing the semiconductor memory device including a protection circuit according to the first embodiment;

FIG. 13 is a perspective view schematically showing a configuration of the circuit diagram shown in FIG. 11;

FIG. 14 is a perspective view schematically showing a configuration of the circuit diagram shown in FIG. 11;

FIG. 15 is a perspective view schematically showing a configuration of the circuit diagram shown in FIG. 12;

FIG. 16 is a schematic circuit diagram showing a configuration of a semiconductor memory device including a protection circuit according to a comparative example;

FIG. 17 is a schematic layout diagram showing the semiconductor memory device including a protection circuit according to the comparative example;

FIG. 18 is a perspective view schematically showing a configuration of the circuit diagram shown in FIG. 16;

FIG. 19 is a schematic circuit diagram showing a path along which ESD current I_{esd} flows, according to the first embodiment;

FIG. 20 is a perspective view schematically showing a configuration of the circuit diagram showing the path along which ESD current I_{esd} flows, according to the first embodiment;

FIG. 21 is a schematic layout diagram showing a circuit configuration of a semiconductor memory device including a protection circuit according to a second embodiment;

FIG. 22 is a perspective view schematically showing a circuit configuration of the semiconductor memory device including a protection circuit according to the second embodiment; and

FIG. 23 is a schematic circuit diagram showing a configuration of the semiconductor memory device including a protection circuit according to the second embodiment.

### DETAILED DESCRIPTION

A semiconductor memory device according to one embodiment comprises: a semiconductor substrate; a plurality of conductive layers stacked in a stacking direction intersecting a surface of the semiconductor substrate; a semiconductor column extending in the stacking direction and facing the plurality of conductive layers; an electric charge accumulating film provided between the plurality of conductive layers and the semiconductor column; a plurality of pad electrodes provided on an opposite side to the semiconductor substrate in the stacking direction with respect to the plurality of conductive layers; a wiring layer provided between the semiconductor substrate and the plurality of conductive layers; and a plurality of via contact electrodes extending in the stacking direction and provided between the plurality of pad electrodes and the wiring layer, the plurality of via contact electrodes being electrically connected to the plurality of pad electrodes and to a wiring included in the wiring layer.

The plurality of pad electrodes include: a first pad electrode having an input signal inputted thereto or an output signal outputted therefrom; a second pad electrode applied with a first voltage; and a third pad electrode applied with a second voltage different from the first voltage.

The semiconductor substrate is provided with: a first transistor and a first diode electrically connected to the first pad electrode and the second pad electrode; a second transistor and a second diode electrically connected to the first pad electrode and the third pad electrode; and a clamp circuit electrically connected to the second pad electrode and the third pad electrode.

The plurality of via contact electrodes include a first via contact electrode, a second via contact electrode, a third via contact electrode, a fourth via contact electrode, a fifth via contact electrode, a sixth via contact electrode, and a seventh via contact electrode. The first via contact electrode is provided at a position overlapping the first pad electrode viewed from the stacking direction and is electrically connected to the first pad electrode. The second via contact electrode is provided at a position overlapping the second pad electrode viewed from the stacking direction and is electrically connected to the second pad electrode and the first transistor. The third via contact electrode is provided at a position overlapping the second pad electrode viewed from the stacking direction and is electrically connected to the second pad electrode and the first diode. The fourth via contact electrode is provided at a position overlapping the second pad electrode viewed from the stacking direction and is electrically connected to the second pad electrode and the clamp circuit. The fifth via contact electrode is provided at a position overlapping the third pad electrode viewed from the stacking direction and is electrically connected to the third pad electrode and the second transistor. The sixth via contact electrode is provided at a position overlapping the third pad electrode viewed from the stacking direction and is electrically connected to the third pad electrode and the second diode. The seventh via contact electrode is provided at a position overlapping the third pad electrode viewed from the stacking direction and is electrically connected to the third pad electrode and the clamp circuit.

The wiring layer comprises: a first wiring commonly connected to the second via contact electrode, the third via contact electrode, and the fourth via contact electrode; and a second wiring commonly connected to the fifth via contact electrode, the sixth via contact electrode, and the seventh via contact electrode.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been serially connected, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are serially connected, and the second configuration is connected to the third configuration via the first configuration.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along the certain plane will sometimes be referred to as a second direction, and a direction intersecting the certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

### First Embodiment

### [Circuit Configuration of Memory Die MD]

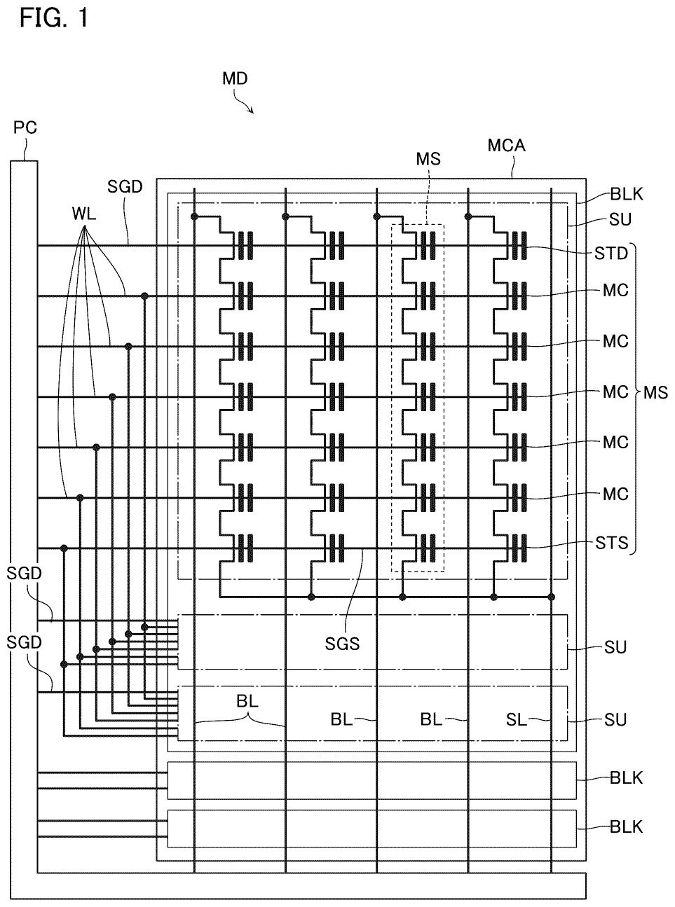

FIG. 1 is a schematic circuit diagram showing a part of a configuration of a memory die MD. As shown in FIG. 1, the memory die MD comprises a memory cell array MCA and a peripheral circuit PC. As shown in FIG. 1, the memory cell array MCA comprises a plurality of memory blocks BLK. These plurality of memory blocks BLK each comprise a plurality of string units SU. These plurality of string units SU each comprise a plurality of memory strings MS. One ends of these plurality of memory strings MS are respectively connected to the peripheral circuit PC via bit lines BL. Moreover, the other ends of these plurality of memory strings MS are each connected to the peripheral circuit PC via a common source line SL.

The memory string MS comprises a drain side select transistor STD, a plurality of memory cells MC (memory transistors), and a source side select transistor STS. The drain side select transistor STD, the plurality of memory cells MC, and the source side select transistor STS are connected in series between the bit line BL and the source line SL. Hereafter, the drain side select transistor STD and the source side select transistor STS will sometimes simply be referred to as select transistors (STD, STS).

The memory cell MC is a field effect type transistor. The memory cell MC comprises a semiconductor layer, a gate insulating film, and a gate electrode. The semiconductor layer functions as a channel region. The gate insulating film includes an electric charge accumulating film. A threshold voltage of the memory cell MC changes according to an amount of charge in the electric charge accumulating film. The memory cell MC stores 1 bit or a plurality of bits of data. Note that the gate electrodes of the plurality of memory cells MC corresponding to one memory string MS are respectively connected with word lines WL. These word lines WL are respectively commonly connected to all of the memory strings MS in one memory block BLK.

The select transistors (STD, STS) are field effect type transistors. The select transistors (STD, STS) each comprise a semiconductor layer, a gate insulating film, and a gate electrode. The semiconductor layer functions as a channel region. The gate insulating film may include an electric charge accumulating film. The gate electrodes of the select transistors (STD, STS) are respectively connected with select gate lines (SGD, SGS). One drain side select gate line SGD is commonly connected to all of the memory strings MS in one string unit SU. One source side select gate line SGS is commonly connected to all of the memory strings MS in one memory block BLK.

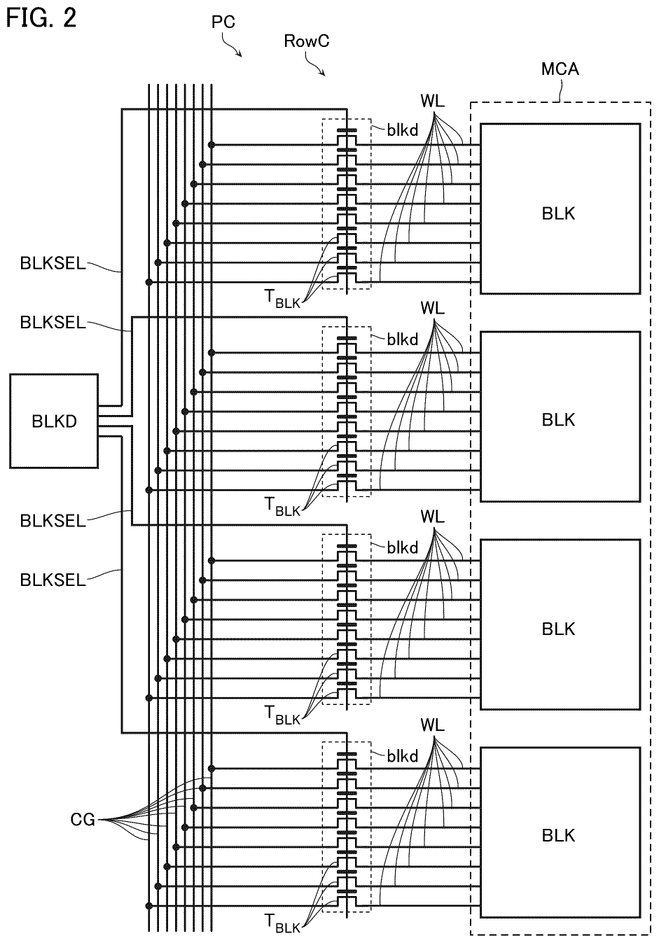

FIG. 2 is a schematic circuit diagram showing a part of a configuration of the peripheral circuit PC. As shown in FIG. 2, for example, the peripheral circuit PC comprises a row control circuit RowC. The row control circuit RowC comprises a plurality of block decode units blkd and a block decoder BLKD.

The plurality of block decode units blkd correspond to the plurality of memory blocks BLK in the memory cell array MCA. The block decode unit blkd comprises a plurality of transistors T_{BLK}. The plurality of transistors T_{BLK} correspond to the plurality of word lines WL in the memory block BLK. The transistor T_{BLK} is a field effect type NMOS transistor, for example. A drain electrode of the transistor T_{BLK} is connected to the word line WL. A source electrode of the transistor T_{BLK} is connected to a wiring CG. The wiring CG is connected to all of the block decode units blkd in the row control circuit RowC. A gate electrode of the transistor T_{BLK} is connected to a signal supply line BLKSEL. A plurality of the signal supply lines BLKSEL are provided correspondingly to all of the block decode units blkd. Moreover, the signal supply line BLKSEL is connected to all of the transistors T_{BLK} in the block decode unit blkd.

The block decoder BLKD decodes a block address during a read operation or a write operation. Moreover, one of the plurality of signal supply lines BLKSEL is set to an “H” state and the remaining signal supply lines BLKSEL are set to an “L” state, depending on the block address that has been decoded.

### [Structure of Memory Die MD]

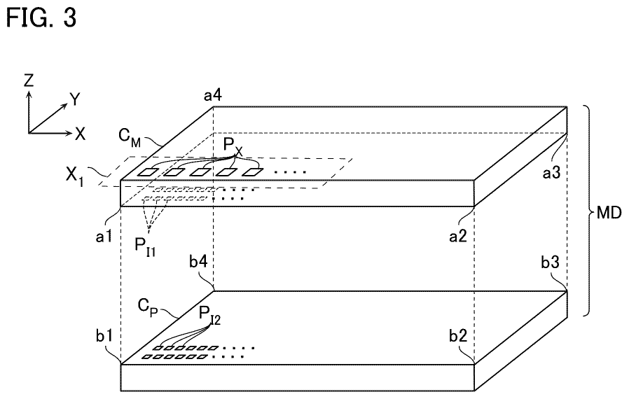

FIG. 3 is a schematic exploded perspective view showing a configuration example of a semiconductor memory device according to the present embodiment. As shown in FIG. 3, the memory die MD comprises: a chip C_{M} on a memory cell array MCA side; and a chip C_{P} on a peripheral circuit PC side.

An upper surface of the chip C_{M} is provided with a plurality of external pad electrodes P_{X} connectable to unillustrated bonding wires. Moreover, a lower surface of the chip C_{M} is provided with a plurality of bonding electrodes P_{I1}. Moreover, an upper surface of the chip C_{P} is provided with a plurality of bonding electrodes P_{I2}. Hereafter, a surface provided with the plurality of bonding electrodes P_{I1}, of the chip C_{M} will be referred to as a front surface of the chip C_{M}, and a surface provided with the plurality of external pad electrodes P_{X}, of the chip C_{M} will be referred to as a back surface of the chip C_{M}. Moreover, a surface provided with the plurality of bonding electrodes P_{I2}, of the chip C_{P} will be referred to as a front surface of the chip C_{P}, and a surface on an opposite side to the front surface, of the chip C_{P} will be referred to as a back surface of the chip C_{P}. In the example illustrated, the front surface of the chip C_{P} is provided above the back surface of the chip C_{P}, and the back surface of the chip C_{M} is provided above the front surface of the chip C_{M}.

The chip C_{M} and the chip C_{P} are disposed so that the front surface of the chip C_{M} and the front surface of the chip C_{P} face each other. The plurality of bonding electrodes P_{I1} are respectively provided correspondingly to the plurality of bonding electrodes P_{I2}, and are disposed at positions enabling them to be bonded to the plurality of bonding electrodes P_{I2}. The bonding electrodes P_{I1} and the bonding electrodes P_{I2} function as bonding electrodes for bonding and making electrically continuous the chip C_{M} and chip C_{P}.

Note that in the example of FIG. 3, corners a1, a2, a3, a4 of the chip C_{M} respectively correspond to corners b1, b2, b3, b4 of the chip C_{P}.

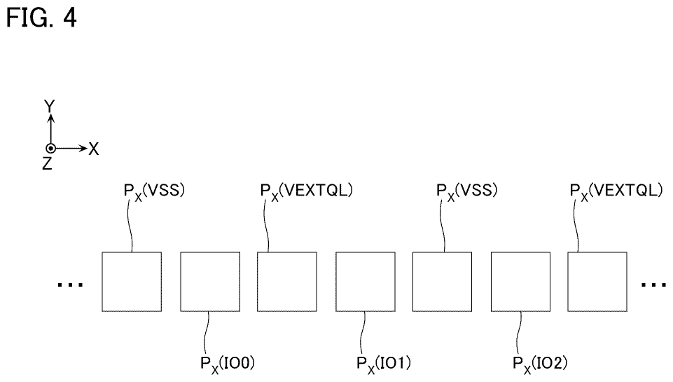

FIG. 4 is a plan view schematically showing arrangement of the plurality of external pad electrodes according to the present embodiment. In the upper surface of the chip C_{M}, the plurality of external pad electrodes P_{X} are arranged in the X-direction.

A part of the plurality of external pad electrodes P_{X} are employed in transfer of an input signal and an output signal. Hereafter, such external pad electrodes P_{X} will sometimes be referred to as external pad electrodes P_{X}(IO0), P_{X}(IO1), P_{X}(IO2), P_{X}(IO3) . . . Moreover, a part of the plurality of external pad electrodes P_{X} are employed in supply of a ground voltage VSS. Hereafter, such external pad electrodes P_{X} will sometimes be referred to as external pad electrodes P_{X}(VSS). Moreover, a part of the plurality of external pad electrodes P_{X} are employed in supply of a drive voltage VEXTQL. Hereafter, such external pad electrodes P_{X} will sometimes be referred to as external pad electrodes P_{X}(VEXTQL).

The external pad electrodes P_{X}(IO0), P_{X}(IO1), P_{X}(IO2), P_{X}(IO3) . . . employed in transfer of input signals and output signals and the external pad electrodes P_{X}(VSS), P_{X}(VEXTQL) employed in apply of voltages are arranged alternately in the X-direction. For example, in the example of FIG. 4, those external pad electrodes P_{X} provided at even-numbered positions, of the plurality of external pad electrodes P_{X} arranged from the −X-direction to the +X-direction correspond to the external pad electrodes P_{X}(IO0), P_{X}(IO1), P_{X}(IO2), P_{X}(IO3) . . . . Moreover, those external pad electrodes P_{X} provided at 4n+1-th positions (where n is an integer of 0 or more), of these plurality of external pad electrodes P_{X} correspond to the external pad electrodes P_{X}(VSS). Moreover, those external pad electrodes P_{X} provided at 4n+3-th positions, of these plurality of external pad electrodes P_{X} correspond to the external pad electrodes P_{X}(VEXTQL).

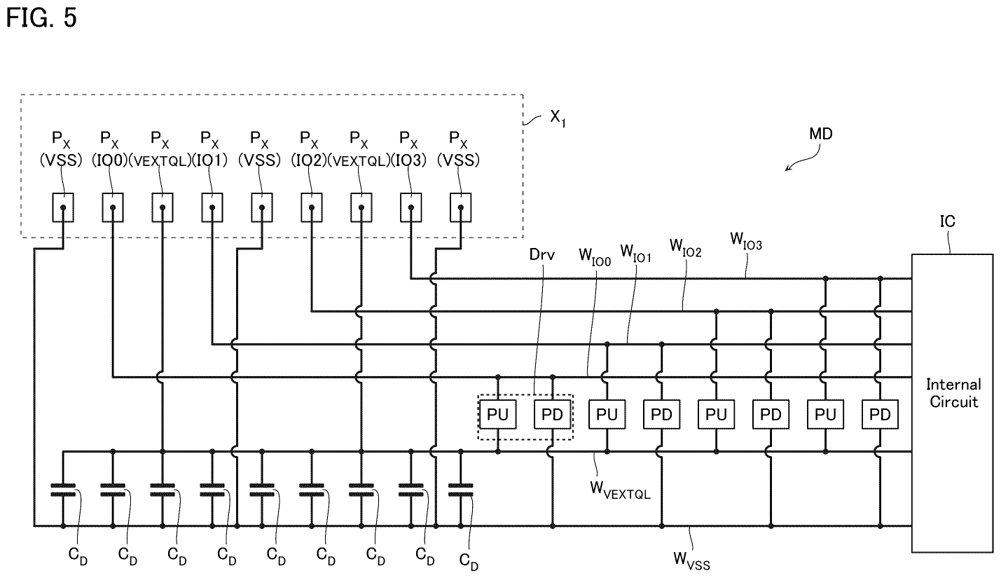

FIGS. 5 to 7 are schematic circuit diagrams showing a part of a configuration of the memory die MD. As shown in FIG. 5, the memory die MD comprises: the plurality of external pad electrodes P_{X}; a plurality of decoupling capacitors Co connected to these plurality of external pad electrodes P_{X}; and an internal circuit IC connected to these plurality of external pad electrodes P_{X}.

The plurality of external pad electrodes P_{X} shown in range X₁ of FIG. 5 correspond to the plurality of external pad electrodes P_{X} shown in range X₁ of FIG. 3. Parts of the plurality of external pad electrodes P_{X} are connected to input/output signal lines W_{IO0}, W_{IO1}, W_{IO2}, W_{IO3} . . . that transfer input signal and output signals. These plurality of input/output signal lines W_{IO0}, W_{IO1}, W_{IO2}, W_{IO3} . . . are connected to an unillustrated comparator, or the like, included in the internal circuit IC.

The input/output signal lines W_{IO0}, W_{IO1}, W_{IO2}, W_{IO3} . . . are respectively connected with driver circuits Drv. The driver circuit Drv includes a pull-down circuit PD and a pull-up circuit PU.

A part of the plurality of external pad electrodes P_{X} is connected to a voltage transfer line W_{VSS} that applies the ground voltage VSS to each of configurations in the memory die MD. The voltage transfer line W_{VSS} is connected to the internal circuit IC.

Moreover, as shown in FIG. 5, a part of the plurality of external pad electrodes P_{X} is connected to a voltage transfer line W_{VEXTQL} that applies the drive voltage VEXTQL to each of configurations in the memory die MD. The voltage transfer line W_{VEXTQL} is connected to the internal circuit IC.

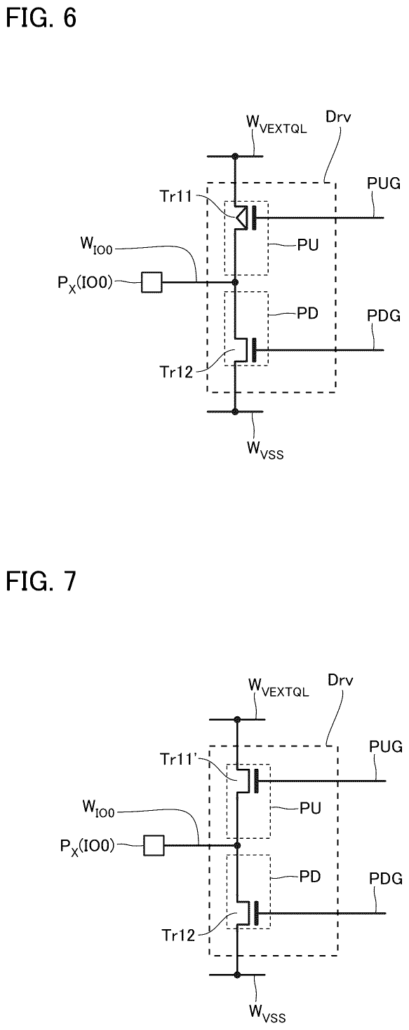

The pull-down circuits PD are respectively connected between the voltage transfer line W_{VSS} and each of the input/output signal lines W_{IO0}, W_{IO1}, W_{IO2}, W_{IO3}. . . . As shown in FIG. 6, the pull-down circuits PD include a plurality of transistors Tr12 connected in parallel between the voltage transfer line W_{VSS} and the input/output signal lines W_{IO0}, W_{IO1}, W_{IO2}, W_{IO3} . . . . A gate electrode of the transistor Tr12 is connected with a signal line PDG. The transistor Tr12, which is an N-type MOS transistor (an NMOS transistor), for example, functions as a pull-down transistor.

Moreover, the pull-up circuits PU are respectively connected between the voltage transfer line W_{VEXTQL} and each of the input/output signal lines W_{IO0}, W_{IO1}, W_{IO2}, W_{IO3} . . . . As shown in FIG. 6, the pull-up circuits PU include a plurality of transistors Tr11 connected in parallel between the voltage transfer line W_{VEXTQL} and the input/output signal lines W_{IO0}, W_{IO1}, W_{IO2}, W_{IO3} . . . . A gate electrode of the transistor Tr11 is connected with a signal line PUG. The transistor Tr11, which is a P-type MOS transistor (a PMOS transistor), for example, functions as a pull-up transistor.

Although FIG. 6 has shown an example where the driver circuit Drv includes the PMOS transistor Tr11 as the pull-up transistor and the NMOS transistor Tr12 as the pull-down transistor, the present invention is not limited to this. For example, as shown in FIG. 7, the pull-up circuit PU may include a plurality of NMOS transistors Tr11′ connected in parallel between the voltage transfer line W_{VEXTQL} and the input/output signal lines W_{IO0}, W_{IO1}, W_{IO2}, W_{IO3} . . . . In this case, the driver circuit Drv is configured by the NMOS transistor Tr11′ as the pull-up transistor and the NMOS transistor Tr12 as the pull-down transistor.

As shown in FIG. 5, the plurality of decoupling capacitors C_{D} are connected in parallel between the voltage transfer line W_{VSS} and the voltage transfer line W_{VEXTQL}.

The internal circuit IC includes the memory cell array MCA and peripheral circuit PC described with reference to FIG. 1. The peripheral circuit PC drives the pull-down circuits PD or pull-up circuits PU corresponding to the input/output signal lines W_{IO0}, W_{IO1}, W_{IO2}, W_{IO3} . . . during output of data. This results in the input/output signal lines W_{IO0}, W_{IO1}, W_{IO2}, W_{IO3} . . . being electrically continuous with the voltage transfer line W_{VSS} or voltage transfer line W_{VEXTQL}.

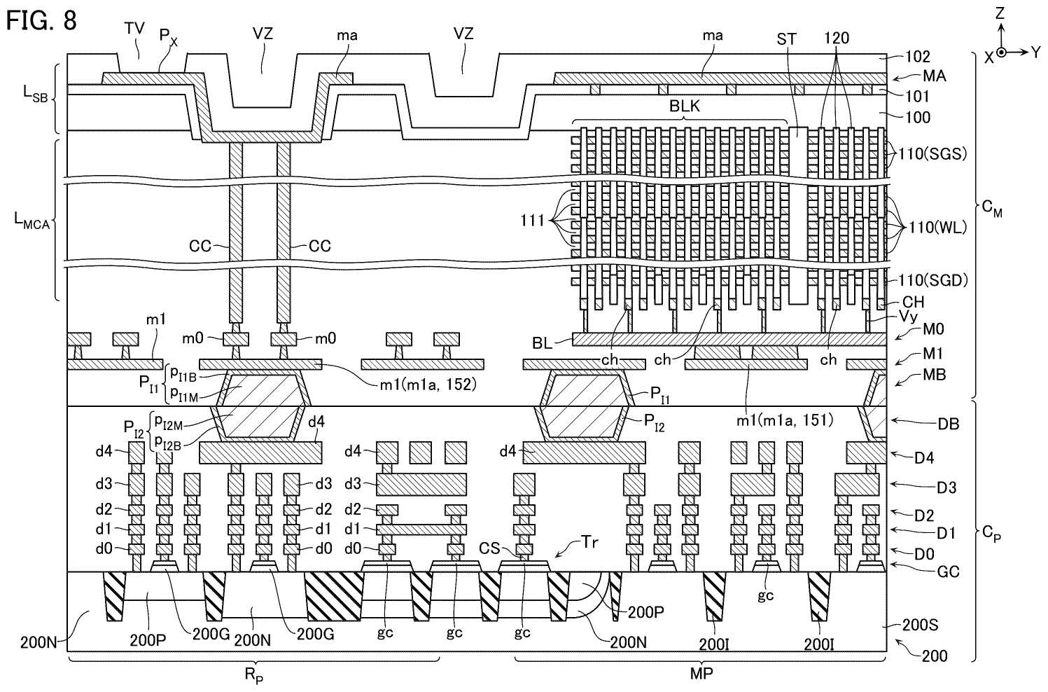

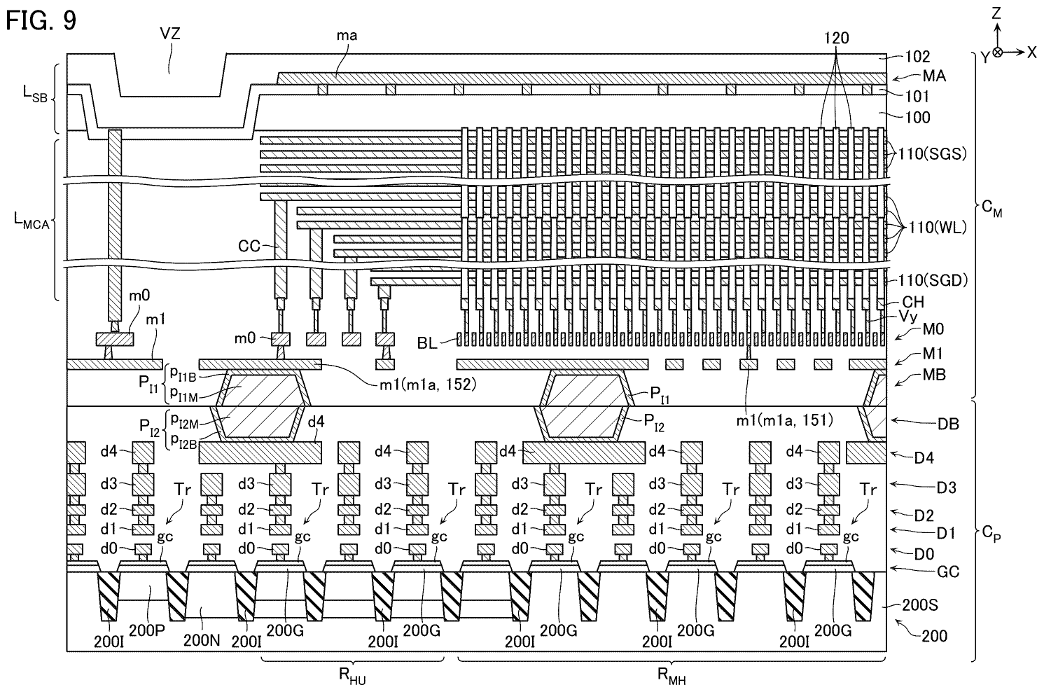

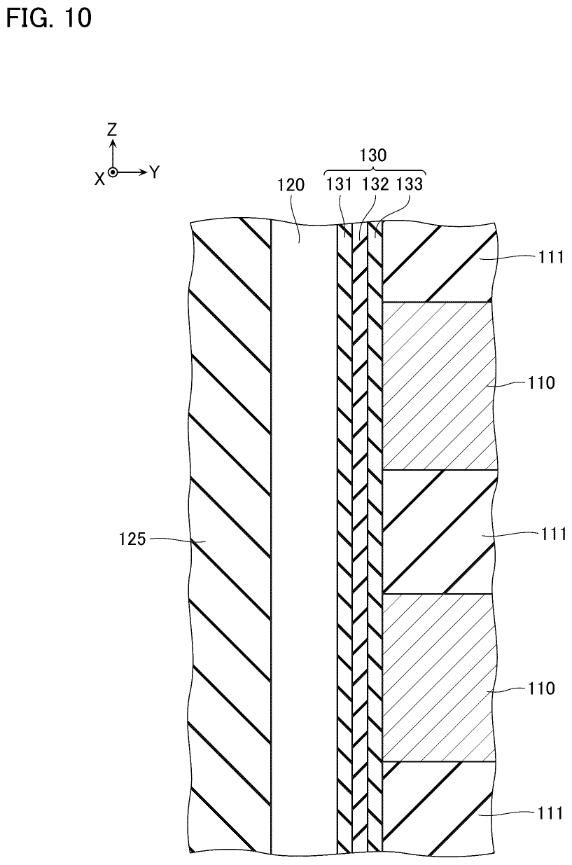

FIGS. 8 and 9 are schematic cross-sectional views showing parts of configurations of the memory die MD. FIG. 10 is a schematic cross-sectional view showing a part of a configuration of the chip C_{M}. Although FIG. 10 shows a YZ cross section, a similar structure to in FIG. 10 will also be observed in the case where a cross section other than a YZ cross section (for example, an XZ cross section) along a central axis of a semiconductor column 120 has been observed.

### [Structure of Chip C_{M}]

As shown in FIG. 8, for example, the chip C_{M} comprises: a substrate layer L_{SB}; a memory cell array layer L_{MCA} provided below the substrate layer L_{SB}; a via contact electrode layer CH provided below the memory cell array layer L_{MCA}; a plurality of wiring layers M0, M1 provided below the via contact electrode layer CH; and a chip bonding electrode layer MB provided below the wiring layers MO, M1.

[Structure of Substrate Layer L_{SB} of Chip C_{M}]

As shown in FIG. 8, for example, the substrate layer L_{SB} comprises: a conductive layer 100 provided on an upper surface of the memory cell array layer L_{MCA}; an insulating layer 101 provided on an upper surface of the conductive layer 100; a back surface wiring layer MA provided on an upper surface of the insulating layer 101; and an insulating layer 102 provided on an upper surface of the back surface wiring layer MA.

The conductive layer 100 may include a semiconductor layer of the likes of silicon (Si) implanted with an N-type impurity such as phosphorus (P) or P-type impurity such as boron (B), may include a metal of the likes of tungsten (W), or may include a silicide of the likes of tungsten silicide (WSi), for example.

The conductive layer 100 functions as a part of the source line SL (FIG. 1). The conductive layer 100 is provided correspondingly to a memory plane MP. End portions in the X-direction and the Y-direction of the memory plane MP are provided with a region VZ that does not include the conductive layer 100.

The insulating layer 101 includes the likes of silicon oxide (SiO₂), for example.

The back surface wiring layer MA includes a plurality of wirings ma. These plurality of wirings ma may include the likes of aluminum (Al), for example.

A part of the plurality of wirings ma functions as part of the source line SL (FIG. 1). This wiring ma is provided correspondingly to the memory plane MP. Each such wiring ma is electrically connected to the conductive layer 100.

Moreover, a part of the plurality of wirings ma functions as the external pad electrode P_{X}. This wiring ma is provided in a peripheral region R_{P}. This wiring ma is connected to a via contact electrode CC within the memory cell array layer L_{MCA} in the region VZ not including the conductive layer 100. Moreover, a part of the wiring ma is exposed to outside of the memory die MD via an opening TV provided in the insulating layer 102.

The insulating layer 102 is a passivation layer consisting of an insulating material such as a polyimide, for example.

[Structure in Memory Hole Region R_{MH} of Memory Cell Array Layer L_{MCA} of Chip C_{M}]

As shown in FIG. 8, the memory cell array layer L_{MCA} is provided with a plurality of the memory blocks BLK arranged in the Y-direction. As shown in FIG. 8, an inter-block insulating layer ST of the likes of silicon oxide (SiO₂) is provided between two memory blocks BLK adjacent in the Y-direction.

For example, as shown in FIG. 8, the memory block BLK comprises: a plurality of conductive layers 110 arranged in the Z-direction; and a plurality of the semiconductor columns 120 extending in the Z-direction. Moreover, as shown in FIG. 10, a gate insulating film 130 is provided between each of the plurality of conductive layers 110 and plurality of semiconductor columns 120.

The conductive layer 110 comprises a substantially plate-like shape extending in the X-direction. The conductive layer 110 may include a stacked film having stacked therein a barrier conductive film of the likes of titanium nitride (TiN) and a metal film of the likes of tungsten (W) or molybdenum (Mo), and so on. Moreover, the conductive layer 110 may include the likes of polycrystalline silicon including an impurity such as phosphorus (P) or boron (B), for example. An inter-layer insulating layer 111 of the likes of silicon oxide (SiO₂) is provided between the plurality of conductive layers 110 arranged in the Z-direction.

One or a plurality of conductive layers 110 located in the uppermost layer, of the plurality of conductive layers 110 function as the gate electrodes of the source side select transistors STS (FIG. 1) and as the source side select gate line SGS (refer to FIG. 8). These plurality of conductive layers 110 are electrically independent every memory block BLK.

Moreover, a plurality of conductive layers 110 located below these uppermost layer-located conductive layers 110 function as the gate electrodes of the memory cells MC (FIG. 1) and as the word lines WL. These plurality of conductive layers 110 are each electrically independent every memory block BLK.

Moreover, one or a plurality of conductive layers 110 located below these word line WL-functioning conductive layers 110, function as the gate electrodes of the drain side select transistors STD (FIG. 1) and as the drain side select gate line SGD.

The semiconductor columns 120 respectively function as channel regions of the plurality of memory cells MC and select transistors (STD, STS) included in one memory string MS (FIG. 1). The semiconductor column 120 includes the likes of polycrystalline silicon (Si), for example. The semiconductor column 120 has a substantially cylindrical shape, and has its central portion provided with an insulating layer 125 (FIG. 10) of the likes of silicon oxide. An outer peripheral surface of the semiconductor column 120 is surrounded by each of a plurality of the conductive layers 110, and faces these plurality of conductive layers 110.

Moreover, an upper end of the semiconductor column 120 is provided with an unillustrated impurity region. This impurity region is connected to the above-described conductive layer 100 (refer to FIG. 8). This impurity region includes an N-type impurity such as phosphorus (P) or a P-type impurity such as boron (B), for example.

Moreover, a lower end of the semiconductor column 120 is provided with an unillustrated impurity region. This impurity region is connected to the bit line BL via a via contact electrode ch and a via contact electrode Vy. This impurity region includes an N-type impurity such as phosphorus (P), for example.

As shown in FIG. 10, for example, the gate insulating film 130 comprises a tunnel insulating film 131, an electric charge accumulating film 132, and a block insulating film 133 that are stacked between the semiconductor column 120 and the conductive layer 110. The tunnel insulating film 131 and the block insulating film 133 include the likes of silicon oxide (SiO₂) or silicon oxynitride (SiON), for example. The electric charge accumulating film 132 includes a film capable of accumulating an electric charge, of the likes of silicon nitride (SiN), for example. The tunnel insulating film 131, the electric charge accumulating film 132, and the block insulating film 133 have substantially cylindrical shapes, and extend in the Z-direction along the outer peripheral surface of the semiconductor column 120 excluding a contact portion of the semiconductor column 120 and the conductive layer 100.

Note that FIG. 10 has shown an example where the gate insulating film 130 comprises the electric charge accumulating film 132 of the likes of silicon nitride. However, the gate insulating film 130 may comprise a floating gate of the likes of polycrystalline silicon including an N-type or P-type impurity, for example.

[Structure in Hook-Up Region R_{HU} of Memory Cell Array Layer L_{MCA} of Chip C_{M}]

As shown in FIG. 9, a hook-up region R_{HU} is provided with a plurality of the via contact electrodes CC. These plurality of via contact electrodes CC each extend in the Z-direction and are connected at their upper ends to the conductive layers 110.

[Structure in Peripheral Region R_{P} of Memory Cell Array Layer L_{MCA} of Chip C_{M}]

As shown in FIG. 8, for example, a plurality of the via contact electrodes CC are provided in the peripheral region R_{P}, correspondingly to the external pad electrodes P_{X}. These plurality of via contact electrodes CC are connected at their upper ends to the external pad electrode P_{X}.

### [Structure of Via Contact Electrode Layer CH]

A plurality of the via contact electrodes ch included in the via contact electrode layer CH are electrically connected to at least one of configurations in the memory cell array layer L_{MCA} and configurations in the chip C_{P}, for example.

The via contact electrode layer CH includes the plurality of via contact electrodes ch as a plurality of wirings. These plurality of via contact electrodes ch may include for example a stacked film having stacked therein a barrier conductive film of the likes of titanium nitride (TiN) and a metal film of the likes of tungsten (W), and so on. The via contact electrodes ch, which are provided correspondingly to the plurality of semiconductor columns 120, are connected to the lower ends of the plurality of semiconductor columns 120.

### [Structure of Wiring Layers M0, M1 of Chip C_{M}]

A plurality of wirings included in the wiring layers M0, M1 are electrically connected to at least one of configurations in the memory cell array layer L_{MCA} and configurations in the chip C_{P}, for example.

The wiring layer M0 includes a plurality of wirings m0. These plurality of wirings m0 may include for example a stacked film having stacked therein a barrier conductive film of the likes of titanium nitride (TiN) and a metal film of the likes of copper (Cu), and so on. Note that a part of the plurality of wirings m0 functions as the bit lines BL. The bit lines BL are arranged in the X-direction as shown in FIG. 9, and extend in the Y-direction as shown in FIG. 8, for example.

As shown in FIG. 8, for example, the wiring layer M1 includes a plurality of wirings m1. These plurality of wirings m1 may include for example a stacked film having stacked therein a barrier conductive film of the likes of titanium nitride (TiN) and a metal film of the likes of tungsten (W), and so on. Note that a wiring pattern in the wiring layer M1 will be mentioned later.

### [Structure of Chip Bonding Electrode Layer MB]

A plurality of wirings included in the chip bonding electrode layer MB are electrically connected to at least one of configurations in the memory cell array layer L_{MCA} and configurations in the chip C_{P}, for example.

The chip bonding electrode layer MB includes a plurality of the bonding electrodes P_{I1}. These plurality of bonding electrodes P_{I1} may include for example a stacked film having stacked therein a barrier conductive film p_{I1B} of the likes of titanium nitride (TiN) and a metal film p_{I1M} of the likes of copper (Cu), for example.

### [Structure of Chip C_{P}]

The chip C_{P} is provided with the plurality of block decode units blkd and the block decoder BLKD described with reference to FIG. 2. Moreover, the chip C_{P} is provided with the decoupling capacitors C_{D}, pull-up circuits PU, and pull-down circuits PD described with reference to FIG. 5.

As shown in FIG. 8, for example, the chip C_{P} comprises: a semiconductor substrate 200; an electrode layer GC provided above the semiconductor substrate 200; wiring layers D0, D1, D2, D3, D4 provided above the electrode layer GC; and a chip bonding electrode layer DB provided above the wiring layers D0, D1, D2, D3, D4.

### [Structure of Semiconductor Substrate 200 of Chip C_{P}]

The semiconductor substrate 200 includes P-type silicon (Si) that includes a P-type impurity such as boron (B), for example. A surface of the semiconductor substrate 200 is provided with, for example: an N-type well region 200N including an N-type impurity such as phosphorus (P); a P-type well region 200P including a P-type impurity such as boron (B); a semiconductor substrate region 200S where the N-type well region 200N and the P-type well region 200P are not provided; and an insulating region 2001. A part of the P-type well regions 200P is provided in the semiconductor substrate region 200S, and a part of the P-type well regions 200P is provided in the N-type well region 200N. The N-type well region 200N, the P-type well regions 200P provided in the N-type well region 200N and semiconductor substrate region 200S, and each of the semiconductor substrate regions 200S functions as parts of a plurality of transistors Tr and a plurality of capacitors, and so on, configuring the peripheral circuit PC.

### [Structure of Electrode Layer GC of Chip C_{P}]

The electrode layer GC is provided on an upper surface of the semiconductor substrate 200 via an insulating layer 200G. The electrode layer GC includes a plurality of electrodes gc that face the surface of the semiconductor substrate 200. Moreover, each of the regions of the semiconductor substrate 200 and the plurality of electrodes gc included in the electrode layer GC are each connected to a via contact electrode CS.

The N-type well region 200N, the P-type well regions 200P provided in the N-type well region 200N and semiconductor substrate region 200S, and the semiconductor substrate region 200S, of the semiconductor substrate 200 respectively function as channel regions of the plurality of transistors Tr and as one of electrodes of the plurality of capacitors, and so on, configuring the peripheral circuit PC.

The plurality of electrodes gc included in the electrode layer GC respectively function as gate electrodes of the plurality of transistors Tr and as the other of the electrodes of the plurality of capacitors, and so on, configuring the peripheral circuit PC.

The via contact electrode CS extends in the Z-direction, and is connected at its lower end to an upper surface of the semiconductor substrate 200 or the electrode gc. A connecting portion of the via contact electrode CS and semiconductor substrate 200 is provided with an impurity region including an N-type impurity or P-type impurity. The via contact electrode CS may include for example a stacked film having stacked therein a barrier conductive film of the likes of titanium nitride (TiN) and a metal film of the likes of tungsten (W), and so on.

### [Structure of Wiring Layers D0, D1, D2, D3, D4 of Chip C_{P}]

As shown in FIG. 8, for example, a plurality of wirings included in the wiring layers D0, D1, D2, D3, D4 are electrically connected to at least one of configurations in the memory cell array layer L_{MCA} and configurations in the chip C_{P}, for example.

The wiring layers D0, D1, D2 respectively include pluralities of wirings d0, d1, d2. These plurality of wirings d0, d1, d2 may include for example a stacked film having stacked therein a barrier conductive film of the likes of titanium nitride (TiN) and a metal film of the likes of tungsten (W), and so on.

The wiring layers D3, D4 respectively include pluralities of wirings d3, d4. These pluralities of wirings d3, d4 may include for example the likes of a stacked film having stacked therein: a barrier conductive film of the likes of titanium nitride (TiN), tantalum nitride (TaN), or a stacked film of tantalum nitride (TaN) and tantalum (Ta); and a metal film of the likes of copper (Cu).

### [Structure of Chip Bonding Electrode Layer DB]

A plurality of wirings included in the chip bonding electrode layer DB are electrically connected to at least one of configurations in the memory cell array layer Luca and configurations in the chip C_{P}, for example.

The chip bonding electrode layer DB includes a plurality of the bonding electrodes P_{I2}. These plurality of bonding electrodes P_{I2} may include for example the likes of a stacked film having stacked therein: a barrier conductive film p_{I2B} of the likes of titanium nitride (TiN), tantalum nitride (TaN), or a stacked film of tantalum nitride (TaN) and tantalum (Ta); and a metal film p_{I2M} of the likes of copper (Cu).

Now, when the metal films p_{I1m}, p_{I2M} of the likes of copper (Cu) are employed in the bonding electrode P_{I1} and the bonding electrode P_{I2}, the metal film p_{I1M} and the metal film p_{I2M} become one metal film, so that identification of their boundary with each other becomes difficult. However, due to distortion of shape where the bonding electrode P_{I1} and the bonding electrode P_{I2} have been bonded resulting from positional shift of bonding, and due to positional shift (generation of discontinuous places in side surfaces) of the barrier conductive films p_{I1B}, p_{I2B}, bonding structure can be identified. Moreover, when the bonding electrode P_{I1} and the bonding electrode P_{I2} are formed by a damascene method, their respective side surfaces will have a tapered shape. Therefore, shape of a cross section along the Z-direction in a portion where the bonding electrode P_{I1} and the bonding electrode P_{I2} have been bonded will be non-rectangular due to side walls being non-linearly shaped. Moreover, when the bonding electrode P_{I1} and the bonding electrode P_{I2} are bonded, there will be a structure where each of a bottom surface, side surface, and upper surface of the Cu forming them will be covered by a barrier metal. In contrast, in a general wiring layer employing Cu, the upper surface of the Cu is provided with an insulating layer (of the likes of SiN or SiCN) functioning to prevent oxidation of the Cu, and is not provided with a barrier metal. Therefore, distinction from a general wiring layer is possible, even when positional shift of bonding has not occurred.

### [Protection Circuit]

Sometimes, when a difference between an amount of charge that has accumulated in the memory cell MC and an amount of charge that has accumulated in the likes of a test device is large, electro-static discharge (ESD: Electro-Static Discharge) will occur, and a large current will flow in the external pad electrode P_{X}. Electro-static discharge includes for example a charged device model (CDM: Charged Device Model), a machine model (MM: Machine Model), a human body model (HBM: Human Body Model), and so on.

The semiconductor memory device according to the present embodiment comprises a protection circuit to prevent the internal circuit (the memory cell array MCA of FIG. 1, and so on) of the semiconductor memory device from being damaged by such electro-static discharge.

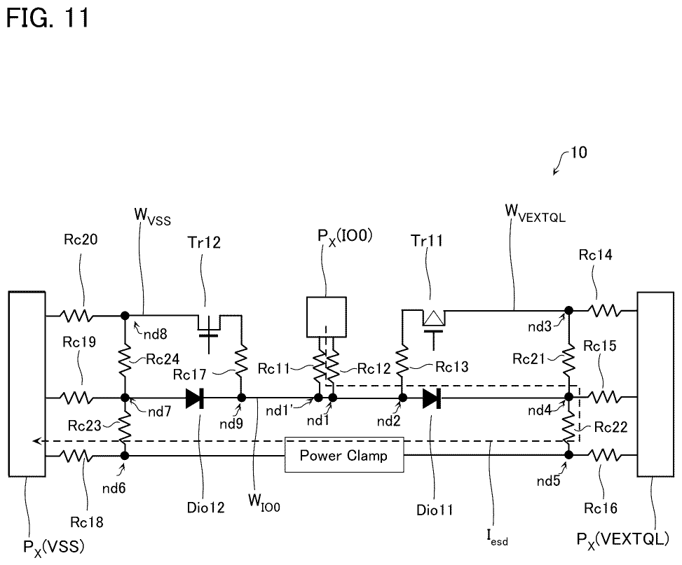

FIG. 11 is a schematic circuit diagram showing a configuration of a semiconductor memory device 10 including the protection circuit according to the present embodiment. In FIG. 11, some configurations are omitted.

The semiconductor memory device 10 including the protection circuit according to the present embodiment comprises: the external pad electrode P_{X}(VSS); the external pad electrode P_{X}(100); the external pad electrode P_{X}(VEXTQL); a power clamp being the clamp circuit; the transistors Tr11, Tr12 described with reference to FIG. 6; and protection diodes Dio11, Dio12 being protection elements.

The semiconductor memory device 10 further comprises a resistance Rc11, a resistance Rc12, a resistance Rc13, a resistance Rc14, a resistance Rc15, a resistance Rc16, a resistance Rc17, a resistance Rc18, a resistance Rc19, a resistance Rc20, a resistance Rc21, a resistance Rc22, a resistance Rc23, and a resistance Rc24.

FIG. 11 further shows a node nd1, a node nd1′, a node nd2, a node nd3, a node nd4, a node nd5, a node nd6, a node nd7, a node nd8, and a node nd9.

The resistances Rc11, Rc12 are electrically connected between the external pad electrode P_{X}(100) and the nodes nd1, nd1′. Now, the resistances Rc11, Rc12 correspond to resistances of those via contact electrodes CC provided between the external pad electrode P_{X}(100) and the nodes nd1, nd1′, of the via contact electrodes CC described with reference to FIG. 8. Note that the node nd1 and the node nd1′, and later-mentioned node nd2 and node nd9 are parts of the input/output signal line Wo described with reference to FIGS. 5 and 6, and are electrically common.

The resistances Rc14, Rc15, Rc16 are electrically connected between the external pad electrode P_{X}(VEXTQL) and the nodes nd3, nd4, nd5. Now, the resistances Rc14, Rc15, Rc16 correspond to resistances of those via contact electrodes CC provided between the external pad electrode P_{X}(VEXTQL) and the nodes nd3, nd4, nd5, of the via contact electrodes CC described with reference to FIG. 8. Note that the node nd3, the node nd4, and the node nd5 are parts of the voltage transfer line W_{VEXTQL} described with reference to FIGS. 5 and 6, and are electrically common.

The resistances Rc18, Rc19, Rc20 are electrically connected between the external pad electrode P_{X}(VSS) and the nodes nd6, nd7, nd8. Now, the resistances Rc18, Rc19, Rc20 correspond to resistances of those via contact electrodes CC provided between the external pad electrode P_{X}(VSS) and the nodes nd6, nd7, nd8, of the via contact electrodes CC described with reference to FIG. 8. Note that the node nd6, the node nd7, and the node nd8 are parts of the voltage transfer line W_{VSS} described with reference to FIGS. 5 and 6, and are electrically common.

The resistance Rc21 is electrically connected between the node nd3 and the node nd4. The resistance Rc22 is electrically connected between the node nd4 and the node nd5. Now, the resistances Rc21, Rc22 are parasitic resistances (internal resistances) of the voltage transfer line W_{VEXTQL} described with reference to FIGS. 5 and 6, and have sufficiently small resistance values compared to a resistance value of the via contact electrode CC, for example.

The Resistance Rc23 is electrically connected between the node nd6 and the node nd7. The resistance Rc24 is electrically connected between the node nd7 and the node nd8. Now, the resistances Rc23, Rc24 are parasitic resistances (internal resistances) of the voltage transfer line W_{VSS} described with reference to FIGS. 5 and 6, and have sufficiently small resistance values compared to a resistance value of the via contact electrode CC, for example.

One of a source and drain (one end) of the transistor Tr11 is electrically connected to the node nd2 via the resistance Rc13, and the other of the source and drain (the other end) of the transistor Tr11 is electrically connected to node nd3. Now, the resistance Rc13 is a parasitic resistance (internal resistance) of a wiring electrically connecting the one of the source and drain (the one end) of the transistor Tr11 and the node nd2, and has a sufficiently small resistance value compared to a resistance value of the via contact electrode CC, for example.

An anode of the protection diode Dio11 is electrically connected to the node nd2, and a cathode of the protection diode Dio11 is electrically connected to the node nd4. Now, the protection diode Dio11 is a PN diode, for example.

The power clamp is electrically connected between the node nd5 and the node nd6. The power clamp is an element that when a voltage applied thereto exceeds a certain value, short-circuits the external pad electrode P_{X}(VEXTQL) and external pad electrode P_{X}(VSS). The power clamp, which is configured by a diode, for example, may be configured by an RCTMOS (Resistance Capacitor Triggered Metal Oxide Semiconductor) circuit.

One of a source and drain (one end) of the transistor Tr12 is electrically connected to the node nd8, and the other of the source and drain (the other end) of the transistor Tr12 is electrically connected to the node nd9 via the resistance Rc17. Now, the resistance Rc17 is a parasitic resistance (internal resistance) of a wiring electrically connecting the other of the source and drain (the other end) of the transistor Tr12 and the node nd9, and has a sufficiently small resistance value compared to a resistance value of the via contact electrode CC, for example.

An anode of the protection diode Dio12 is electrically connected to the node nd7, and a cathode of the protection diode Dio12 is electrically connected to the node nd9. Now, the protection diode Dio12 is a PN diode, for example.

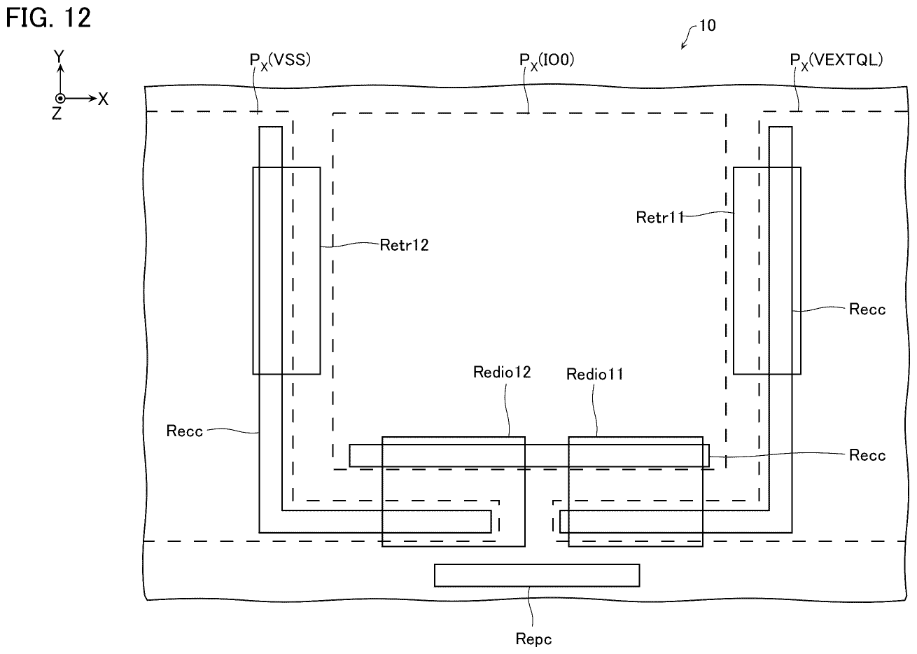

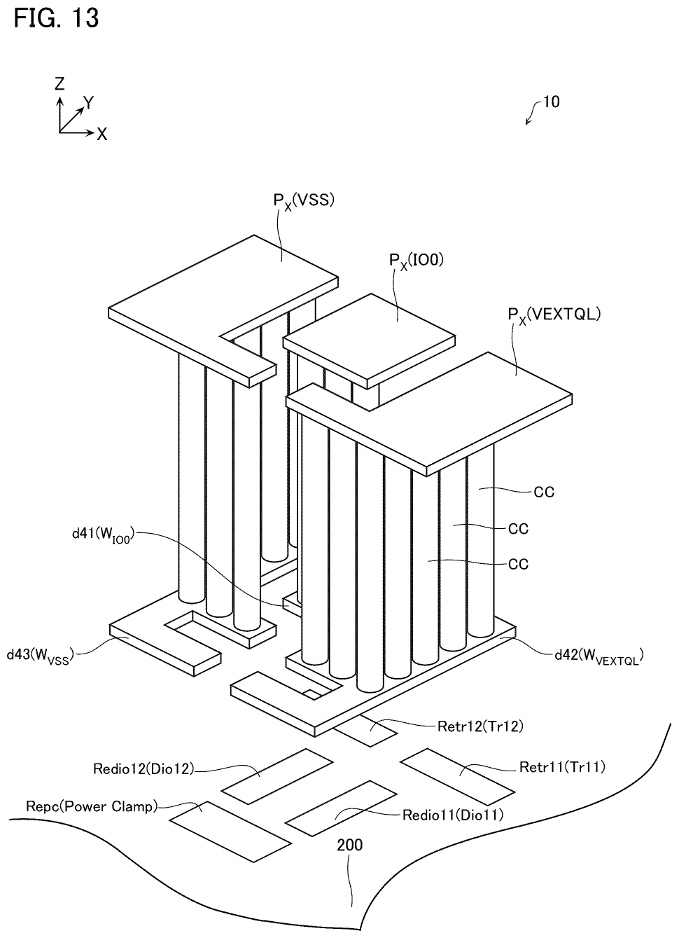

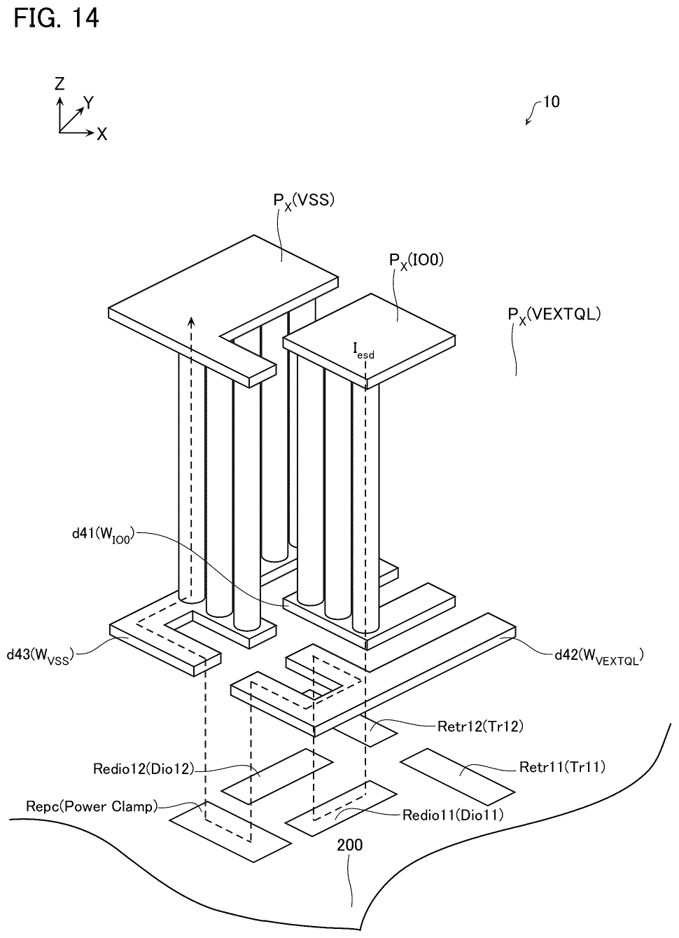

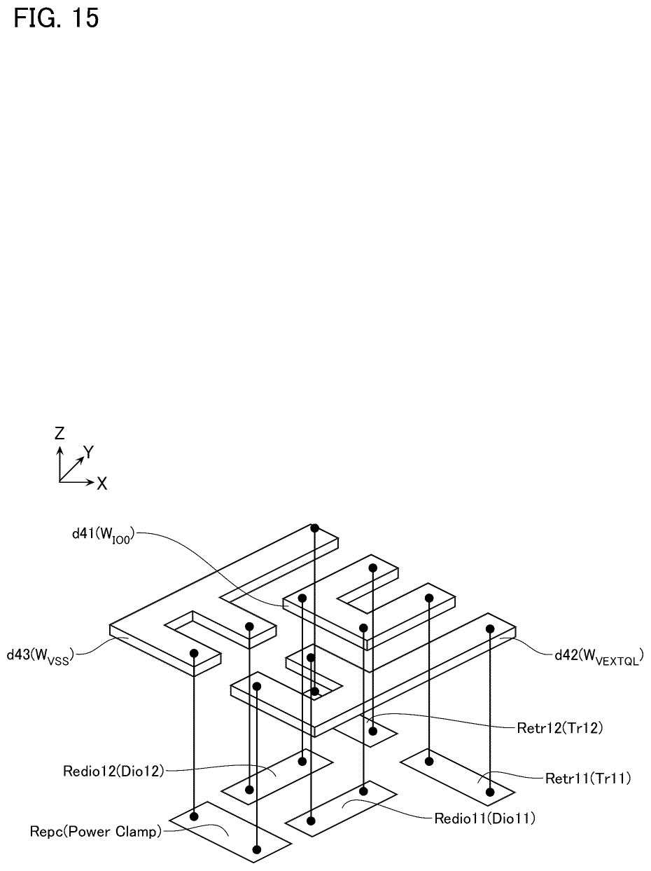

FIG. 12 is a schematic layout diagram showing the semiconductor memory device 10 including the protection circuit according to the present embodiment. FIGS. 13 to 15 are perspective views schematically showing a configuration of the circuit diagram shown in FIG. 12. In FIGS. 12 and 13, some configurations are omitted. In FIGS. 14 and 15, parts of the structure shown in FIG. 13 are further omitted.

In FIG. 12, a region of the external pad electrode P_{X}(100), a region of the external pad electrode P_{X}(VEXTQL), and a region of the external pad electrode P_{X}(VSS) are shown by dotted lines.

As shown in FIG. 12, a region Recc is disposed on a side at one end in the Y-direction (a lower side in the drawing) of the region of the external pad electrode P_{X}(100). As shown in FIG. 13, in this region Recc, a plurality of the via contact electrodes CC are arranged in the X-direction along the one end in the Y-direction of the external pad electrode P_{X}(100).

Moreover, as shown in FIG. 12, regions Redio11, Redio12 are arranged in the X-direction at positions overlapping this region Recc viewed from the Z-direction. The region Redio11 is disposed on an external pad electrode P_{X}(VEXTQL) side in the X-direction, and the region Redio12 is disposed on an external pad electrode P_{X}(VSS) side in the X-direction. As shown in FIG. 13, the regions Redio11, Redio12 on the semiconductor substrate 200 are provided with the protection diodes Dio11, Dio12 described with reference to FIG. 11.

Moreover, as shown in FIG. 12, a region Repc is disposed on one side in the Y-direction (an opposite side to the region of the external pad electrode P_{X}(100)) with respect to the regions Redio11, Redio12. As shown in FIG. 13, the region Repc on the semiconductor substrate 200 is provided with the power supply clamp circuit described with reference to FIG. 11.

Moreover, as shown in FIG. 12, a region Recc is also disposed in a region on an external pad electrode P_{X}(100) side in the X-direction and a region on one side in the Y-direction (a lower side in the drawing), of the region of the external pad electrode P_{X}(VEXTQL). As shown in FIG. 13, in this region Recc, a plurality of the via contact electrodes CC are arranged in the Y-direction along one end in the X-direction of the external pad electrode P_{X}(VEXTQL). Moreover, in this region Recc, a plurality of the via contact electrodes CC are arranged in the X-direction along one end in the Y-direction of the external pad electrode P_{X}(VEXTQL).

Moreover, as shown in FIG. 12, a region Retr11 is disposed at a position overlapping this region Recc viewed from the Z-direction. As shown in FIG. 13, the region Retr11 on the semiconductor substrate 200 is provided with a plurality of the transistors Tr11 described with reference to FIGS. 6 and 11.

Moreover, as shown in FIG. 12, a region Recc is also disposed in a region on an external pad electrode P_{X}(100) side in the X-direction and a region on one side in the Y-direction (a lower side in the drawing), of the region of the external pad electrode P_{X}(VSS). As shown in FIG. 13, in this region Recc, a plurality of the via contact electrodes CC are arranged in the Y-direction along one end in the X-direction of the external pad electrode P_{X}(VSS). Moreover, in this region Recc, a plurality of the via contact electrodes CC are arranged in the X-direction along one end in the Y-direction of the external pad electrode P_{X}(VSS).

Moreover, as shown in FIG. 12, a region Retr12 is disposed at a position overlapping this region Recc viewed from the Z-direction. As shown in FIG. 13, the region Retr12 on the semiconductor substrate 200 is provided with a plurality of the transistors Tr12 described with reference to FIGS. 6 and 11.

Moreover, in the present embodiment, the wiring layer D4 described with reference to FIGS. 8 and 9 comprises wirings d41, d42, d43 as a part of the wirings d4.

The wiring d41 functions as the input/output signal line W_{IO0}. The wiring d41 includes: a portion extending in the X-direction along the region Recc corresponding to the external pad electrode P_{X}(IO0); and a pair of portions connected to one end and the other end in the X-direction of this portion, and extending in the Y-direction. As shown in FIG. 15, the portion extending in the X-direction overlaps the regions Redio11, Redio12 viewed from the Z-direction, and is electrically connected to the protection diodes Dio11, Dio12. The portions extending in the Y-direction overlap the regions Retr11, Retr12 viewed from the Z-direction, and are electrically connected to the transistors Tr11, Tr12.

The wiring d42 functions as the voltage transfer line W_{VEXTQL}. The wiring d42 includes: a portion extending in the Y-direction along part of the region Recc corresponding to the external pad electrode P_{X}(VEXTQL); and a pair of portions connected to this portion and extending in the X-direction. As shown in FIG. 15, the portion extending in the Y-direction overlaps the region Retr11 viewed from the Z-direction, and is electrically connected to the transistor Tr11. One of the pair of portions extending in the X-direction is provided along another part of the region Recc corresponding to the external pad electrode P_{X}(VEXTQL). Moreover, this one of the pair of portions overlaps the region Redio11 viewed from the Z-direction, and is electrically connected to the protection diode Dio11. The other of the pair of portions extending in the X-direction overlaps the region Repc viewed from the Z-direction, and is electrically connected to the power supply clamp circuit.

The wiring d43 functions as the voltage transfer line W_{VSS}. The wiring d43 includes: a portion extending in the Y-direction along part of the region Recc corresponding to the external pad electrode P_{X}(VSS); and a pair of portions connected to this portion and extending in the X-direction. As shown in FIG. 15, the portion extending in the Y-direction overlaps the region Retr12 viewed from the Z-direction, and is electrically connected to the transistor Tr12. One of the pair of portions extending in the X-direction is provided along another part of the region Recc corresponding to the external pad electrode P_{X}(VSS). Moreover, this one of the pair of portions overlaps the region Redio12 viewed from the Z-direction, and is electrically connected to the protection diode Dio12. The other of the pair of portions extending in the X-direction overlaps the region Repc viewed from the Z-direction, and is electrically connected to the power supply clamp circuit.

### [Comparative Example]

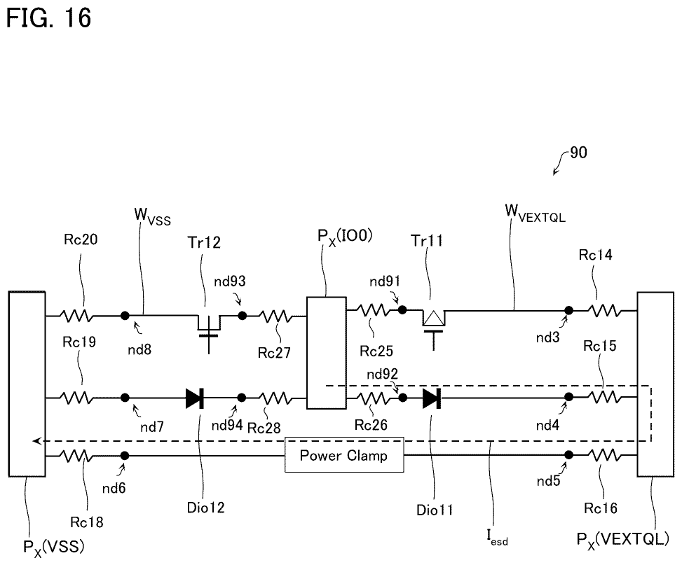

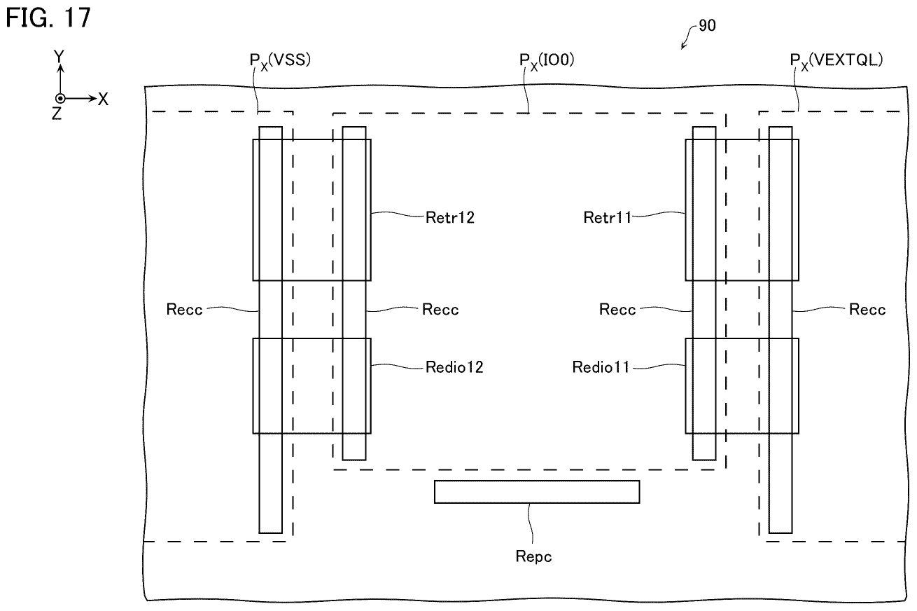

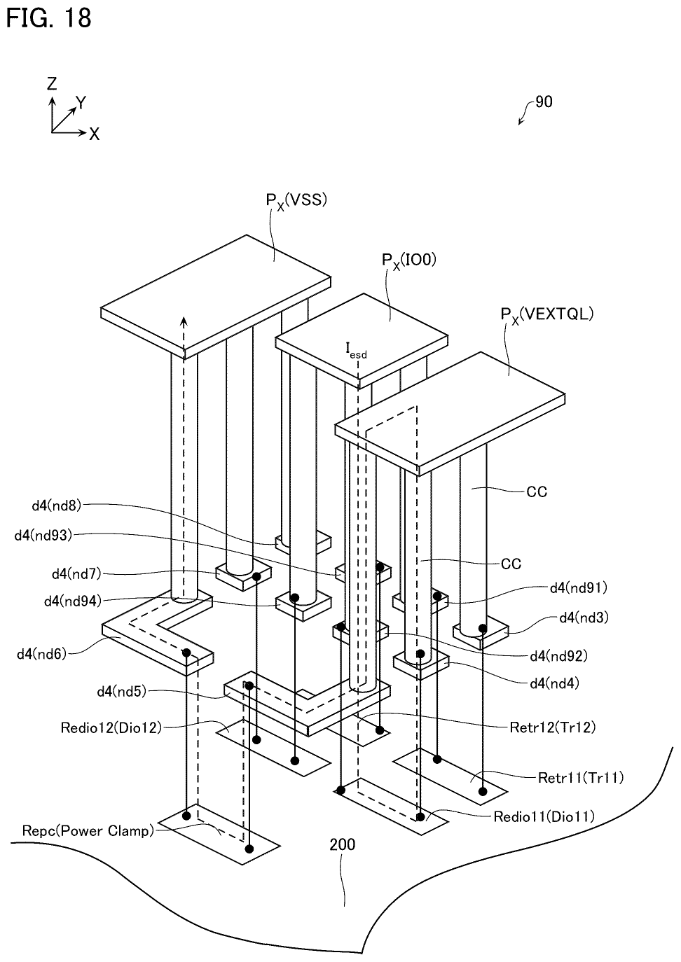

Next, a semiconductor memory device 90 according to a comparative example will be described with reference to FIGS. 16 to 18. FIG. 16 is a schematic circuit diagram showing a configuration of the semiconductor memory device 90 including a protection circuit according to the comparative example. FIG. 17 is a schematic layout diagram showing the semiconductor memory device 90 including a protection circuit according to the comparative example. FIG. 18 is a perspective view schematically showing a configuration of the circuit diagram shown in FIG. 16. In FIGS. 16 to 18, some configurations are omitted.

As shown in FIG. 16, in the semiconductor memory device 90 including a protection circuit according to the comparative example, the nodes nd3, nd4, nd5 are not commonly connected. Moreover, the nodes nd6, nd7, nd8 are not commonly connected.

Moreover, FIG. 16 shows: a node nd91 connected to one of the source and drain (one end) of the transistor Tr11; a resistance Rc25 electrically connected between the node nd91 and the external pad electrode P_{X}(IO0); a node nd92 connected to the anode of the protection diode Dio11; and a resistance Rc26 electrically connected between the node nd92 and the external pad electrode P_{X}(IO0). The resistances Rc25, Rc26 correspond to resistances of those via contact electrodes CC provided between the external pad electrode P_{X}(IO0) and the nodes nd91, nd92, of the via contact electrodes CC.

Provided between the external pad electrodes P_{X}(IO0) and P_{X}(VEXTQL) in the comparative example are: a current path including the resistance Rc14, the transistor Tr11, and the resistance Rc25; and a current path including the resistance Rc15, the protection diode Dio11, and the resistance Rc26. These two current paths are electrically independent.

Moreover, FIG. 16 shows: a node nd93 connected to one of the source and drain (one end) of the transistor Tr12; a resistance Rc27 electrically connected between the node nd93 and the external pad electrode P_{X}(IO0); a node nd94 connected to the cathode of the protection diode Dio12; and a resistance Rc28 electrically connected between the node nd94 and the external pad electrode P_{X}(IO0). The resistances Rc27, Rc28 correspond to resistances of those via contact electrodes CC provided between the external pad electrode P_{X}(IO0) and the nodes nd93, nd94, of the via contact electrodes CC.

Provided between the external pad electrodes P_{X}(IO0) and P_{X}(VSS) in the comparative example are: a current path including the resistance Rc20, the transistor Tr12, and the resistance Rc27; and a current path including the resistance Rc19, the protection diode Dio12, and the resistance Rc28. These two current paths are electrically independent.

Moreover, provided between the external pad electrodes P_{X}(VEXTQL) and P_{X}(VSS) in the comparative example is a current path including the resistance Rc18, the power supply clamp circuit, and the resistance Rc16. This current path is electrically independent from all of the above-mentioned current paths.

Moreover, as shown in FIG. 17, in the comparative example, a region Recc provided with a plurality of the via contact electrodes CC is disposed not on the side at one end in the Y-direction (the lower side in the drawing) of the region of the external pad electrode P_{X}(IO0), but on sides at both ends in the X-direction of the region of the external pad electrode P_{X}(IO0).

Moreover, in the comparative example, the region Redio12 provided with the protection element is provided not on the side at one end in the Y-direction (the lower side in the drawing) of the region of the external pad electrode P_{X}(IO0), but on a side at one end in the X-direction (a side of the region of the external pad electrode P_{X}(VSS) in the drawing) of the region of the external pad electrode P_{X}(IO0).

Moreover, as shown in FIG. 18, in the comparative example, the plurality of wirings d4 in the wiring layer D4 are independent every node nd3, nd4, nd5, nd6, nd7, nd8, nd91, nd92, nd93, nd94.

Now, in recent years, film-thinning of transistors being the elements-to-be-protected has led to a lowering of ESD tolerance, so it has become necessary for ESD tolerance to be secured. Moreover, in order to secure ESD tolerance, it is preferable for impedance to ESD current of the protection circuit to be reduced, and for voltage applied to the element-to-be-protected to be reduced.

However, the fact that in three-dimensionally stacked memory such as NAND flash memory, via contact electrodes CC representing a high resistance exist between external pad electrodes and circuits has been a factor causing increased impedance to ESD current.

For example, when one considers the case where a surge voltage having a positive magnitude has been applied to the external pad electrode P_{X}(IO0), then in the comparative example, as shown in FIGS. 16 and 18, an ESD current I_{esd} will flow in a path that passes in order from the external pad electrode P_{X}(IO0) through the via contact electrode CC (resistance Rc26), the wiring d4 (node nd92), the protection diode Dio11, the wiring d4 (node nd4), the via contact electrode CC (resistance Rc15), the external pad electrode P_{X}(VEXTQL), the via contact electrode CC (resistance Rc16), the wiring d4 (node nd5), the clamp circuit, the wiring d4 (node nd6), the via contact electrode CC (resistance Rc18), and the external pad electrode P_{X}(VSS).

Moreover, the ESD current I_{esd} will not flow in the transistor Tr12 being the element-to-be-protected. Hence, voltage of an electrode on one side of the transistor Tr12 will be equal to that of the external pad electrode P_{X}(IO0). Similarly, voltage of an electrode on the other side of the transistor Tr12 will be equal to that of the external pad electrode P_{X}(VSS).

Hence, in the comparative example, the voltage applied to the transistor Tr12 being the element-to-be-protected upon occurrence of the ESD current I_{esd} will be roughly that calculated by adding a voltage Vf related to the protection diode Dio11, a voltage Vc related to the clamp circuit, and a voltage Vrcc related to the resistances Rc26, Rc15, Rc16, Rc18.

Now, as degree-of-integration of semiconductor memory devices continues to rise, a length in the Z-direction of the via contact electrodes CC is increasing. As a result, resistance values of the resistances Rc26, Rc15, Rc16, Rc18 corresponding to the via contact electrodes CC are increasing. Consequently, the voltage applied to the transistor Tr12 being the element-to-be-protected upon occurrence of the ESD current I_{esd} is increasing.

### [Advantages of Semiconductor Memory Device According to First Embodiment]

In the semiconductor memory device 10 according to the first embodiment, the node nd3, the node nd4, and the node nd5 are commonly electrically connected. Moreover, the node nd6, the node nd7, and the node nd8 are commonly electrically connected. Furthermore, the nodes nd1, nd1′, nd2, nd9 are commonly electrically connected.

When one considers the case where a surge voltage having a positive magnitude has been applied to the external pad electrode P_{X}(IO0) in such a configuration, then, as shown in FIGS. 11, 13, and 14, for example, the ESD current I_{esd} will flow in a path that passes in order from the external pad electrode P_{X}(IO0) through the via contact electrode CC (parallel circuit of the resistances Rc11, Rc12), the wiring d41 (nodes nd1, nd1′), the protection diode Dio11, the wiring d42 (nodes nd4, nd5), the clamp circuit, the wiring d43 (node nd6), the via contact electrode CC (resistance Rc18), and the external pad electrode P_{X}(VSS).

Moreover, the ESD current I_{esd} will not flow in the transistor Tr12 being the element-to-be-protected. Hence, voltage of the electrode on one side of the transistor Tr12 will be equal to that of the node nd9. Similarly, voltage of the electrode on the other side of the transistor Tr12 will be equal to that of the node nd8.

Hence, in the first embodiment, the voltage applied to the transistor Tr12 being the element-to-be-protected upon occurrence of the ESD current I_{esd} will be roughly that calculated by adding the voltage Vf related to the protection diode Dio11 and the voltage Vc related to the clamp circuit. In other words, the voltage applied to the transistor Tr12 being the element-to-be-protected upon occurrence of the ESD current I_{esd} will not include the voltage Vrcc related to the resistances Rc26, Rc15, Rc16, Rc18 of the via contact electrodes CC representing a high resistance. Consequently, the present embodiment makes it possible for the voltage applied to the transistor Tr12 being the element-to-be-protected upon occurrence of the ESD current I_{esd} to be significantly reduced.

Note that an IR drop due to a parasitic resistance (internal resistance) possessed by the resistance Rc13 and the resistance Rc17 shown in FIG. 11, that is, possessed by the wiring d41 (FIG. 13) ends up reducing effects of ESD tolerance degradation.

In this connection, in the present embodiment, as shown in FIGS. 12 to 15, by the protection diode Dio11 and transistor Tr11 being provided adjacently, a length in the Y-direction of the wiring d41 is shortened, and a parasitic resistance of the wiring d41 (a resistance value of the resistance Rc13) thereby lowered. In addition, by the protection diode Dio12 and transistor Tr12 being provided adjacently, the length in the Y-direction of the wiring d41 is shortened, and the parasitic resistance of the wiring d41 (a resistance value of the resistance Rc17) thereby lowered.

Moreover, as shown in FIG. 13, by the protection diode Dio11 being provided in a closer vicinity than is the transistor Tr11, seen from the via contact electrode CC electrically connecting the external pad electrode P_{X}(IO0) and the wiring d41, current flowing in the resistance Rc13 is reduced. Moreover, by the protection diode Dio12 being provided in a closer vicinity than is the transistor Tr12, seen from the via contact electrode CC electrically connecting the external pad electrode P_{X}(IO0) and the wiring d41, current flowing in the resistance Rc17 is reduced.

In this way, effects of the IR drop due to the parasitic resistance (internal resistance) possessed by the resistance Rc13 and the resistance Rc17, that is, possessed by the wiring d41 (FIGS. 13 and 15) can be suppressed.

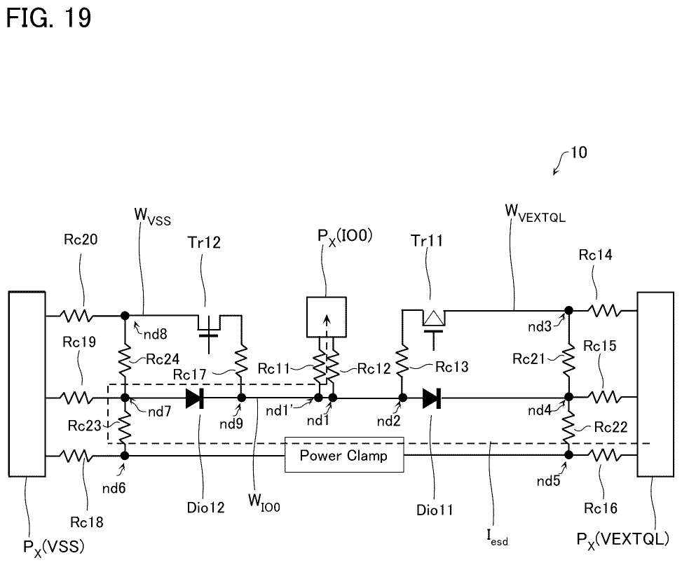

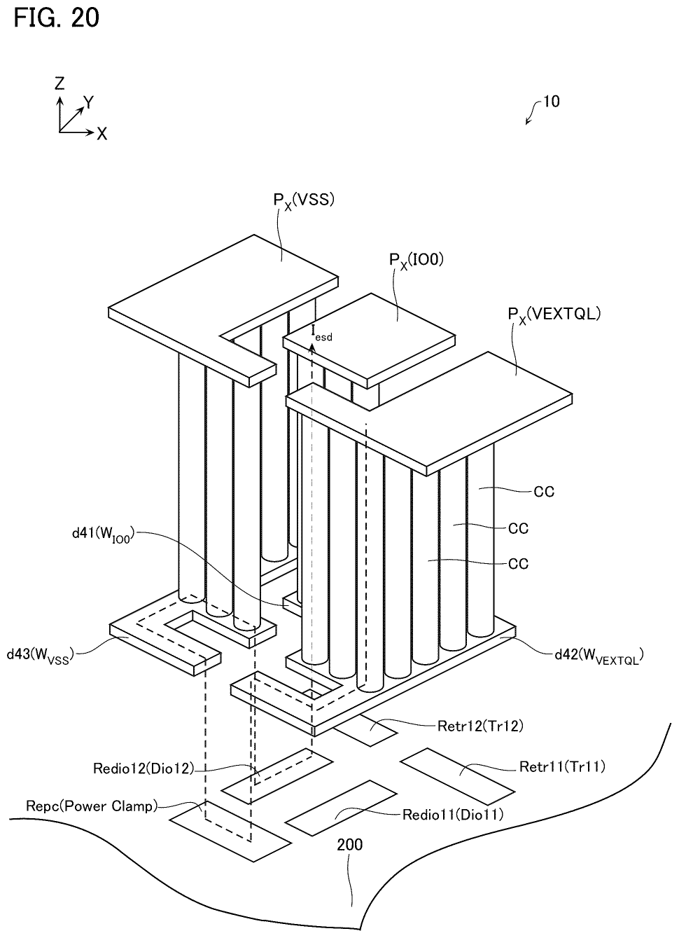

FIG. 19 is a schematic circuit diagram showing the path along which the ESD current I_{esd} flows, according to the first embodiment. FIG. 20 is a perspective view schematically showing a configuration of the circuit diagram showing the path along which the ESD current I_{esd} flows, according to the first embodiment.

Moreover, when one considers the case where a surge voltage having a negative magnitude has been applied to the external pad electrode P_{X}(IO0) in the configuration of the first embodiment, then, as shown in FIGS. 19 and 20, the ESD current I_{esd} will flow in a path that passes in order from the external pad electrode P_{X}(VEXTQL) through the via contact electrode CC (resistance Rc16), the wiring d43 (node nd5), the clamp circuit, the wiring d43 (nodes nd6, nd7), the protection diode Dio12, the wiring d41 (nodes nd1, nd1′), the via contact electrode CC (parallel circuit of the resistances Rc11, Rc12), and the external pad electrode P_{X}(IO0).

Hence, the wiring d41 (nodes nd1, nd1′) and the via contact electrode CC (parallel circuit of the resistances Rc11, Rc12) can be commonly included in the path along which the ESD current I_{esd} flows in the case of a surge voltage with a positive magnitude having been applied and the path along which the ESD current I_{esd} flows in the case of a surge voltage with a negative magnitude having been applied. This makes it possible for the number of via contact electrodes CC connected to the external pad electrode P_{X}(IO0) to be reduced compared to in the case of the comparative example, while securing ESD tolerance. Reducing the number of via contact electrodes CC connected to the external pad electrode P_{X}(IO0) makes it possible for a parasitic capacitance of the external pad electrode P_{X}(IO0) to be reduced, communication between the memory die MD and an external controller die to be speeded up, and operating speed of the memory system to be improved.

### Second Embodiment

A semiconductor memory device 10A according to a second embodiment is basically configured similarly to the semiconductor memory device 10 according to the first embodiment.

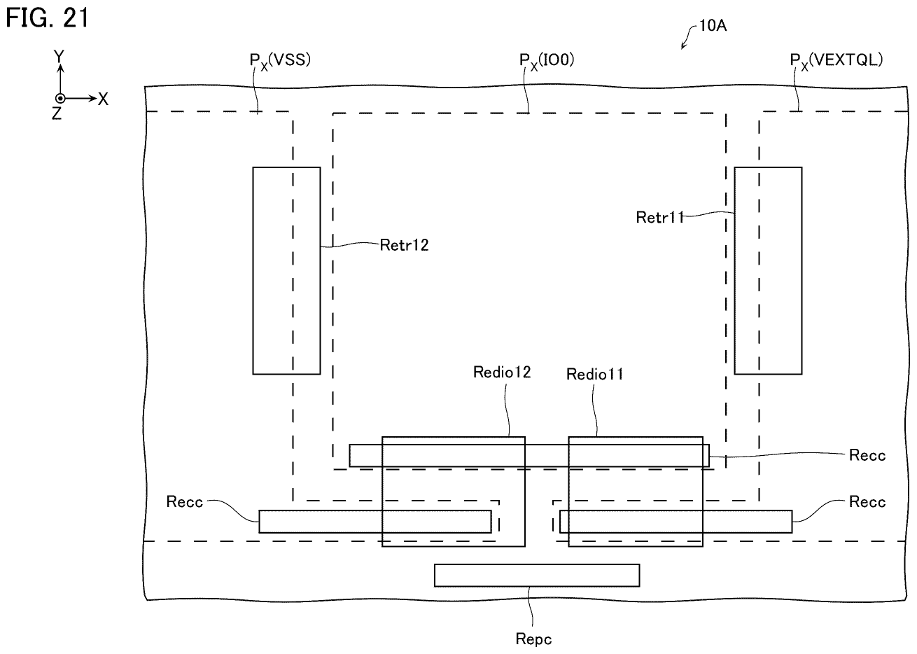

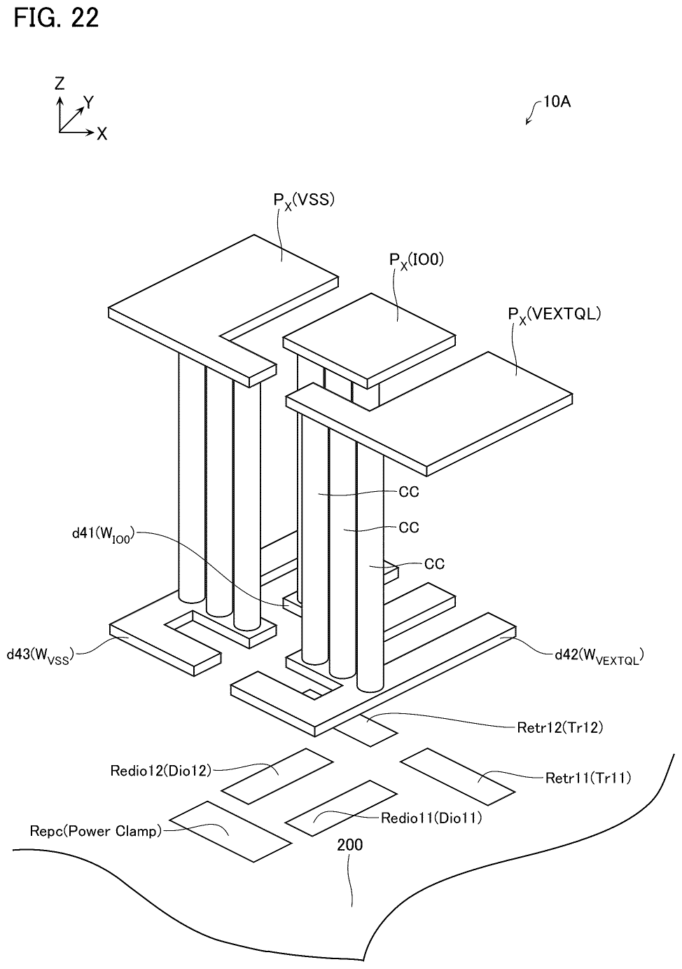

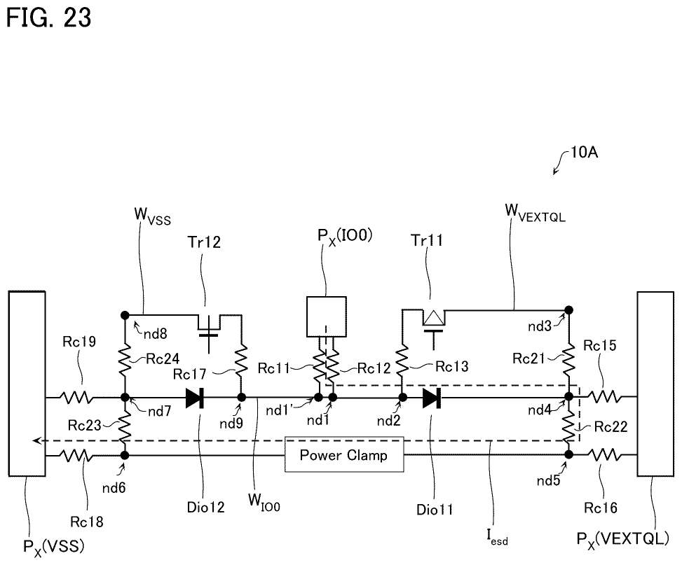

FIG. 21 is a schematic layout diagram showing the semiconductor memory device 10A including a protection circuit according to the present embodiment. FIG. 22 is a perspective view schematically showing a circuit configuration of the semiconductor memory device 10A including a protection circuit according to the second embodiment. FIG. 23 is a schematic circuit diagram showing a configuration of the semiconductor memory device including a protection circuit according to the second embodiment. In FIGS. 21 to 23, some configurations are omitted. In the description below, portions similar to in the first embodiment will be assigned with the same symbols as in the first embodiment, and descriptions thereof omitted.

As described with reference to FIG. 12, in the first embodiment, a region Recc is disposed in a region on an external pad electrode P_{X}(IO0) side in the X-direction of the region of the external pad electrode P_{X}(VEXTQL). Similarly, a region Recc is disposed in a region on an external pad electrode P_{X}(IO0) side in the X-direction of the region of the external pad electrode P_{X}(VSS).

On the other hand, as shown in FIG. 21, in the second embodiment, a region Recc is not disposed in a region on an external pad electrode P_{X}(IO0) side in the X-direction of the region of the external pad electrode P_{X}(VEXTQL). Hence, as shown in FIG. 22, in the second embodiment, a via contact electrode CC is not provided in a region on an external pad electrode P_{X}(IO0) side in the X-direction of the region of the external pad electrode P_{X}(VEXTQL).

Moreover, as shown in FIG. 21, in the second embodiment, a region Recc is not disposed in a region on an external pad electrode P_{X}(IO0) side in the X-direction of the region of the external pad electrode P_{X}(VSS). Hence, as shown in FIG. 22, in the second embodiment, a via contact electrode CC is not provided in a region on an external pad electrode P_{X}(IO0) side in the X-direction of the region of the external pad electrode P_{X}(VSS).

[Advantages of Semiconductor Memory Device according to Second Embodiment]

In the second embodiment, a region Recc is not disposed in a region on an external pad electrode P_{X}(IO0) side in the X-direction of the region of the external pad electrode P_{X}(VEXTQL). In such a configuration, as shown in FIG. 22, a distance from the via contact electrode CC connected to the external pad electrode P_{X}(VSS) to a connecting portion with the transistor Tr12 of the wiring d43 will be larger compared to in the first embodiment. Putting this another way, the path along which the ESD current I_{esd} flows in the case of the external pad electrode P_{X}(IO0) having been applied with a surge voltage having a positive magnitude, and the transistor Tr12 acting as a protection target, will be connected via the resistance Rc24 (FIG. 23). Hence, during ESD occurrence, the voltage applied to the transistor Tr12 can be lowered, and advantages of ESD tolerance in the likes of transistor Tr12 be thereby further heightened.

### [Other Embodiments]

In the above embodiments, there have been described examples where technology described in the present specification is applied to a NAND flash memory. However, the technology described in the present specification may also be applied to configurations of other semiconductor memory devices such as a three-dimensional type NOR flash memory, for example. Moreover, the technology described in the present specification may also be applied to configurations of a semiconductor device other than a semiconductor memory device.

Moreover, in the above embodiments, the transistor Tr11 has been described as a PMOS transistor. However, it is also possible for the transistor Tr11 to be realized by an NMOS transistor.

Moreover, in the above embodiments, a layout of each configuration has been exemplified with reference to FIGS. 17 and 21. However, a specific layout of each configuration is appropriately adjustable. For example, in FIGS. 17 and 21, configurations provided at positions that overlap viewed from the Z-direction may be provided at positions that do not overlap viewed from the Z-direction. Even in such cases, it is possible for their wirings to be drawn around by any one of a plurality of wiring layers provided between the via contact electrodes CC and the semiconductor substrate 200.

Moreover, in the above embodiments, there have been described examples where a plurality of the wirings d4 in the wiring layer D4 are utilized to commonly connect lower ends of the via contact electrodes CC. However, the wirings commonly connecting lower ends of the via contact electrodes CC may be wirings included in a wiring layer other than the wiring layer D4. Moreover, wirings included in a plurality of wiring layers may be utilized to commonly connect lower ends of the via contact electrodes CC.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate;
a plurality of conductive layers stacked in a stacking direction intersecting a surface of the semiconductor substrate;
a semiconductor column extending in the stacking direction and facing the plurality of conductive layers;
an electric charge accumulating film provided between the plurality of conductive layers and the semiconductor column;
a plurality of pad electrodes provided on an opposite side to the semiconductor substrate in the stacking direction with respect to the plurality of conductive layers;
a wiring layer provided between the semiconductor substrate and the plurality of conductive layers; and
a plurality of via contact electrodes extending in the stacking direction and provided between the plurality of pad electrodes and the wiring layer, the plurality of via contact electrodes being electrically connected to the plurality of pad electrodes and to a wiring included in the wiring layer, wherein
the plurality of pad electrodes include:
a first pad electrode having an input signal inputted thereto or an output signal outputted therefrom;
a second pad electrode applied with a first voltage; and
a third pad electrode applied with a second voltage different from the first voltage,
the semiconductor substrate is provided with:
a first transistor and a first diode electrically connected to the first pad electrode and the second pad electrode;
a second transistor and a second diode electrically connected to the first pad electrode and the third pad electrode; and
a clamp circuit electrically connected to the second pad electrode and the third pad electrode,
the plurality of via contact electrodes include:
a first via contact electrode provided at a position overlapping the first pad electrode viewed from the stacking direction and electrically connected to the first pad electrode;
a second via contact electrode provided at a position overlapping the second pad electrode viewed from the stacking direction and electrically connected to the second pad electrode and the first transistor;
a third via contact electrode provided at a position overlapping the second pad electrode viewed from the stacking direction and electrically connected to the second pad electrode and the first diode;
a fourth via contact electrode provided at a position overlapping the second pad electrode viewed from the stacking direction and electrically connected to the second pad electrode and the clamp circuit;
a fifth via contact electrode provided at a position overlapping the third pad electrode viewed from the stacking direction and electrically connected to the third pad electrode and the second transistor;
a sixth via contact electrode provided at a position overlapping the third pad electrode viewed from the stacking direction and electrically connected to the third pad electrode and the second diode; and
a seventh via contact electrode provided at a position overlapping the third pad electrode viewed from the stacking direction and electrically connected to the third pad electrode and the clamp circuit, and
the wiring layer comprises:
a first wiring commonly connected to the second via contact electrode, the third via contact electrode, and the fourth via contact electrode; and
a second wiring commonly connected to the fifth via contact electrode, the sixth via contact electrode, and the seventh via contact electrode.

2. The semiconductor memory device according to claim 1, wherein
the wiring layer further comprises a third wiring commonly connected to the first via contact electrode, the first transistor, the first diode, the second transistor, and the second diode,
the first transistor and the first diode are connected in parallel between the first wiring and the third wiring, and
the second transistor and the second diode are connected in parallel between the second wiring and the third wiring.

3. The semiconductor memory device according to claim 1, wherein
the first transistor is an N channel MOS transistor or a P channel MOS transistor, and
the second transistor is an N channel MOS transistor.

4. The semiconductor memory device according to claim 1, wherein
viewed from the stacking direction, the first diode is provided closer to the first via contact electrode than the first transistor.

5. The semiconductor memory device according to claim 1, wherein
viewed from the stacking direction, the first diode is provided closer to the clamp circuit than the first transistor.

6. The semiconductor memory device according to claim 1, wherein
the clamp circuit is configured by a diode.

7. The semiconductor memory device according to claim 1, wherein
the clamp circuit is configured by an RCTMOS (Resistance Capacitor Triggered Metal Oxide Semiconductor) circuit.

8. The semiconductor memory device according to claim 1 including
a resistance electrically connected in series between the first via contact electrode and the first transistor.

9. The semiconductor memory device according to claim 1, wherein
the first pad electrode, the second pad electrode, and the third pad electrode are provided arranged in order of the third pad electrode, the first pad electrode, and the second pad electrode, in a first direction intersecting the stacking direction.

10. The semiconductor memory device according to claim 1, comprising
a first semiconductor chip and a second semiconductor chip connected to each other via a plurality of bonding electrodes, wherein
the first semiconductor chip comprises:
the semiconductor substrate; and
a plurality of first bonding electrodes being some ones of the plurality of bonding electrodes,
the second semiconductor chip comprises:
the plurality of conductive layers;
the semiconductor column;
the electric charge accumulating film;
the plurality of pad electrodes;
the plurality of via contact electrodes; and
a plurality of second bonding electrodes being other ones of the plurality of bonding electrodes, and
the first semiconductor chip and the second semiconductor chip are disposed so that the plurality of first bonding electrodes face the plurality of second bonding electrodes.

11. A semiconductor memory device comprising:
a semiconductor substrate;
a plurality of conductive layers stacked in a stacking direction intersecting a surface of the semiconductor substrate;
a semiconductor column extending in the stacking direction and facing the plurality of conductive layers;
an electric charge accumulating film provided between the plurality of conductive layers and the semiconductor column;
a plurality of pad electrodes provided on an opposite side to the semiconductor substrate in the stacking direction with respect to the plurality of conductive layers;
a wiring layer provided between the semiconductor substrate and the plurality of conductive layers; and
a plurality of via contact electrodes extending in the stacking direction and provided between the plurality of pad electrodes and the wiring layer, the plurality of via contact electrodes being electrically connected to the plurality of pad electrodes and to a wiring included in the wiring layer, wherein
the plurality of pad electrodes include:
a first pad electrode having an input signal inputted thereto or an output signal outputted therefrom;
a second pad electrode applied with a first voltage; and
a third pad electrode applied with a second voltage different from the first voltage,
the semiconductor substrate is provided with:
a first transistor and a first diode electrically connected to the first pad electrode and the second pad electrode;
a second transistor and a second diode electrically connected to the first pad electrode and the third pad electrode; and
a clamp circuit electrically connected to the second pad electrode and the third pad electrode,
the plurality of via contact electrodes include:
a first via contact electrode provided at a position overlapping the first pad electrode viewed from the stacking direction and electrically connected to the first pad electrode;
a second via contact electrode provided at a position overlapping the second pad electrode viewed from the stacking direction and electrically connected to the second pad electrode and the clamp circuit; and
a third via contact electrode provided at a position overlapping the third pad electrode viewed from the stacking direction and electrically connected to the third pad electrode and the clamp circuit, and
the wiring layer comprises:
a first wiring extending in a direction intersecting the stacking direction, so as to overlap the first transistor and the first diode viewed from the stacking direction, the first wiring being connected to the second via contact electrode; and
a second wiring extending in a direction intersecting the stacking direction, so as to overlap the second transistor and the second diode viewed from the stacking direction, the second wiring being connected to the third via contact electrode.
